(19) United States
(12) Patent Application Publication
(10) Pub. No.: US 2014/0160681 A1
(43) Pub. Date: Jun. 12, 2014

(54) Discrete-Pin Printed-Circuit Mounting with Notches

(71) Applicant: WINTEC INDUSTRIES, INC., Milpitas, CA (US)

(72) Inventor: Kong-Chen Chen, San Jose, CA (US)

(73) Assignee: Wintec Industries, Inc., Milpitas, CA (US)

(21) Appl. No.: 13/708,876

(22) Filed: Dec. 7, 2012

(51) Int. Cl. H05K 1/02; H05K 13/00

(52) U.S. Cl. CPC H05K 1/0298; H05K 13/00; H05K 1/0201
USPC 361/704; 29/825; 361/803

(57) ABSTRACT

An electric apparatus for connecting to a first printed circuit includes a second printed circuit, which includes a first surface substantially parallel to a first plane and a second surface substantially parallel to a second plane perpendicular to the first plane. The first surface includes a first area and the second surface includes a smaller second area. The second printed circuit includes conductive traces in a layer of the second printed circuit. The electric apparatus further includes first and second conductive pins including first and second longitudinal axes, respectively. First and second notches in the second printed circuit include respective first and second openings through the second surface adapted to receive portions of the first and second pins and adapted to electrically connect the pins to first and second respective ones of the conductive traces. The first and second longitudinal axes are installed substantially parallel to the first plane.

### BACKGROUND

The present invention relates generally to printed circuits and in particular, to the electrical interface and attachment of one printed circuit to another.

A printed circuit or printed circuit board (PCB) provides electrical connection to components mounted on its surface to achieve a specific function. It is at times more and advantageous to provide a smaller PCB, hereinafter called a “daughter-board”, “module”, or “electric subassembly” for mechanically attaching and electrically interfacing, hereinafter called “mounting,” to a larger PCB, hereinafter called “mother-board” or “main-board.” Modules enable system designers to add desired application features and reduce main-board surface area. Typically, mounting a module to the main-board requires providing both mechanical support of the module and connects multiple electrical signals between the boards.

A module may be mounted with its component-carrying surface substantially perpendicular to the component-carrying surface of the main-board, hereinafter called “vertical mounting”. Alternatively, a module may be mounted with its component-carrying surface parallel to the component-carrying surface of the main-board, hereinafter called “horizontal mounting” or “mezzanine mounting”.

Vertical mounting of a module has been provided by plating a set of gold fingers along an edge of the module on the board's component mounting surface. The portion of the module with the set of gold fingers plated along an edge may be called an edge connector, for plugging into a corresponding socket on the main-board. The module may be shaped so that the edge connector fits into a socket in just one orientation, a mechanism called “keying”.

Module to main-board mounting is also commonly provided by soldering a pin-strip connector or a pin-strip socket on the module. A pin-strip connector is a set of identical metal pins held together at a uniform pitch by a molded plastic housing. FIG. 1A is a simplified side view of a common pin-strip connector 10. FIG. 1B is a simplified side view of pin-strip connector 10 referenced in FIG. 1A mounted in through-holes on a PCB 12. Because the pins in a pin strip connector are symmetrically spaced, users are often unable to differentiate the mounting orientation of an off-the-shelf pin strip connector into its socket on the main-board, unless some keying mechanism is added to both pin-strip and socket.

Using a pin from an otherwise symmetric pin-strip connector for orientation keying wastes an electrical signal pin location because that pin location is allocated merely for mechanical orientation keying use. For example, the Intel® Z-U130 Value Solid State Drive defines pin 9 of a 2×5 pin-strip connector as a keying pin, i.e. Keyed/DNU (Do Not Use). In product manufacturing, the metal post of pin 9 is often cut-off from the 2×5 pin-strip connector and pin 9 at the corresponding hole in the pin socket on the main-board is filled with a solid material or obstacle to prevent the drive from being inserted into the socket in a reversed orientation due to the otherwise symmetrical construction of the 2×5 pin-strip connector and socket. The excess keying pin is not cost effective because its function is purely mechanical and does not simultaneously carry an electrical signal.

Off-the-shelf pin-strip connectors and sockets have predetermined pin pitch, which may use up more area occupied by that off-the-shelf pin-strip connector or socket on the module and the main-board, and tend to require more height and space, which reduces module efficiency, especially for systems requiring a small form factor.

Individual or discrete pins are available in straight or right angled versions. However, assembling a set of right angle discrete pins to a set of through holes in a module to facilitate vertical mounting is a challenging task because it is not easy to maintain the desired orientation of the discrete pins at right angles to the board edge.

Mounting of modules has also been provided using a board edge rivet mount type connection pin, which has twin parallel plates forming a slot that the module needs to fit between. FIGS. 2A and 2B are simplified side views of a common edge rivet mount pin 14 and its mounting onto a PCB 16, respectively. However, available slot widths are limited, which in-turn, limits the choice of board thickness. For example, board edge rivet mount pins are available from one manufacturer in just two slot widths of 47 mils (0.047″) or 75 mils (0.075″), which limits PCBs to just two thicknesses. Manufacturing a module with board edge rivet mount connection pins is complicated by maintaining the pins at right angles to the board edge during soldering.

### SUMMARY

According to one embodiment of the present invention, an electric apparatus for connecting to a first printed circuit includes a second printed circuit, which includes a first surface substantially parallel to a first plane and a second surface substantially parallel to a second plane perpendicular to the first plane. The first surface includes a first area and the second surface includes a second area smaller than the first area. The second printed circuit further includes a multitude of conductive traces formed in a layer of the second printed circuit substantially parallel to the first plane. The electric apparatus further includes a first conductive pin and a second conductive pin. The first conductive pin includes a first longitudinal axis. The second conductive pin includes a second longitudinal axis. A first notch in the second printed circuit includes a first opening through the second surface adapted to receive a portion of the first conductive pin and adapted to electrically connect the first conductive pin to a first one of the multitude of conductive traces. The first conductive pin is installed in the first notch such that the first longitudinal axis is positioned substantially parallel to the first plane. A second notch in the second printed circuit includes a second opening through the second surface adapted to receive a portion of the second conductive pin and adapted to electrically connect the second conductive pin to a second one of the multitude of conductive traces. The second conductive pin is installed in the second notch such that the second longitudinal axis is positioned substantially parallel to the first plane.

According to one embodiment, the first notch includes a first sidewall not parallel to the first plane. A portion of the first sidewall is overlaid by a conductive layer. According to another embodiment, the electric apparatus further includes a conductive layer overlaying a portion of the first surface adjoining the first notch.

According to another embodiment, the first notch includes a first notch thickness in a direction substantially perpendicular to the first plane. The second printed circuit includes a thickness equal to the first notch thickness.

According to another embodiment, the electric apparatus further includes a third surface on the second printed circuit substantially parallel to a third plane perpendicular to the first plane and to the second plane. The electric apparatus further includes a third notch including an opening through the third surface, the third notch being adapted to engage with a clip or hook when the second printed circuit is connected to the first printed circuit.

According to another embodiment, the installation of the first conductive pin comprises at least one of soldered, press-fit, taped, glued, or glued with conductive paste into the first notch. According to another embodiment, the electric apparatus further includes an epoxy layer overlaying a portion of the first surface adjacent the first notch and overlaying a portion of the first conductive pin. According to another embodiment, the electric apparatus further includes a polyimide film including a sticky silicone adhesive overlaying a portion of the first surface adjacent the first notch and overlaying a portion of the first conductive pin.

According to another embodiment, the first conductive pin includes a first pin width in a direction substantially perpendicular to the first longitudinal axis. The second conductive pin includes a second pin width in a direction substantially perpendicular to the second longitudinal axis. The second pin width is substantially equal to the first pin width.

According to another embodiment, the first conductive pin includes a first pin width in a direction substantially perpendicular to the first longitudinal axis. The second conductive pin includes a second pin width in a direction substantially perpendicular to the second longitudinal axis. The second pin width is different than the first pin width.

According to another embodiment, the first conductive pin includes a first cross sectional area substantially perpendicular to the first longitudinal axis. The second conductive pin includes a second cross sectional area substantially perpendicular to the second longitudinal axis. The second cross sectional area is not equal to the first cross sectional area.

According to another embodiment, the first conductive pin comprises at least one of brass alloy, phosphor bronze alloy, tellurium copper alloy, or conductive carbon composite. According to another embodiment, the first conductive pin is spring-loaded and partially enclosed by a supporting shell adapted to install into the first notch.

According to another embodiment, the first conductive pin includes a first pin width in a direction substantially perpendicular to the first longitudinal axis. The first conductive pin includes a first end and a second end located opposite the first end. The first pin width is a substantially constant value from the first end to the second end.

According to another embodiment, the first conductive pin includes a first length extending beyond the second surface and outside the first notch. The second conductive pin includes a second length extending beyond the second surface and outside the second notch. The second length is different than the first length.

According to another embodiment, the first conductive pin includes a first end and a second end opposite the first end. A portion of the first conductive pin adjacent to the first end is installed in the first notch. A portion adjacent to the second end of the first conductive pin includes threads adapted to receive a nut when the second printed circuit is connected to the first printed circuit.

According to another embodiment, the first conductive pin includes a first end and a second end opposite the first end. A portion of the first conductive pin adjacent to the first end is installed in the first notch and the second end includes a substantially blunt tip. According to another embodiment, the first conductive pin and the second conductive pin are not mechanically coupled until the first conductive pin and the second conductive pin are installed in the first notch and the second notch respectively.

According to another embodiment, the first notch includes a sidewall not parallel to the first plane. A portion of the first conductive pin adjacent to a first end of the first conductive pin is installed in the first notch, the portion being in contact with the sidewall.

According to another embodiment, the electric apparatus further includes a third conductive pin and a third notch in the second printed circuit. The third conductive pin includes a third longitudinal axis. The third notch includes a third opening through the second surface adapted to receive a portion of the third conductive pin and to electrically connect the third conductive pin to a third one of the multitude of conductive traces. The third conductive pin is installed in the third notch such that the third longitudinal axis is positioned substantially parallel to the first plane. The first notch is spaced apart from the second notch at a first spacing in a first direction substantially parallel to an intersection of the first plane and the second plane and the second notch is spaced apart from the third notch at a second spacing in the first direction, the second spacing being different than the first spacing.

According to another embodiment, the first notch includes a first notch thickness in a direction substantially perpendicular to the first plane. The second printed circuit includes a thickness greater than the first notch thickness. According to another embodiment, the first notch includes a third surface substantially parallel to the first plane. According to another embodiment, a portion of the third surface is overlaid by a conductive layer.

According to another embodiment, the electric apparatus further includes a through-hole located within a portion of the third surface and located away from the second surface. The through-hole is adapted to receive the first conductive pin. The first conductive pin further includes a third longitudinal axis substantially perpendicular to the first longitudinal axis. A portion of the first conductive pin along the third longitudinal axis is installed in the through-hole. A portion of the first conductive pin along the first longitudinal axis is installed in the first notch. According to another embodiment, the through-hole includes a sidewall plated with a conductive material.

According to another embodiment, the first conductive pin includes at least one bend. According to another embodiment, the first conductive pin further includes a third longitudinal axis at an angle not less than a right-angle from the first longitudinal axis. A portion of the first conductive pin along the first longitudinal axis is installed in the first notch. A portion of the first conductive pin along the third longitudinal axis is positioned substantially not parallel to the first plane.

According to another embodiment, the first conductive pin includes a first end and a broadened region extending from the first end to a predetermined location along the first longitudinal axis. A portion adjacent to the first end is installed in the first notch. The broadened region is adapted to increase contact between the first notch and the first conductive pin. According to another embodiment, the broadened region includes a bend in the first conductive pin. According to another embodiment, the broadened region includes a flattened region in the first conductive pin.

According to another embodiment, the electric apparatus further includes a third printed circuit including a third surface substantially parallel to the first plane and a fourth surface substantially parallel to the second plane. The third surface includes a third area and the fourth surface includes a fourth area smaller than the third area. The third printed circuit is coupled to the second printed circuit. The electric apparatus further includes a multitude of conductive traces of the third printed circuit formed substantially parallel to the first plane, and a third conductive pin including a third longitudinal axis. The electric apparatus further includes a third notch in the third printed circuit, the third notch including a third opening through the fourth surface adapted to receive a portion of the third conductive pin and adapted to electrically connect the third conductive pin to a first one of the multitude of conductive traces of the third printed circuit. The third conductive pin is installed in the third notch such that the third longitudinal axis is positioned substantially parallel to the first plane.

According to another embodiment, the electric apparatus further includes at least one conductor adapted to electrically connect a corresponding one of the multitude of conductive traces of the third printed circuit to a corresponding one of the multitude of conductive traces of the second printed circuit. According to another embodiment, the electric apparatus further includes a thermally conducting and electrically insulating layer disposed between the second printed circuit and the third printed circuit. According to another embodiment, the electric apparatus further includes a heat dissipater in contact with the thermally conducting and electrically insulating layer. According to another embodiment, the thermally conducting and electrically insulating layer includes a conduction via adapted to electrically connect a corresponding one of the multitude of conductive traces of the third printed circuit to a corresponding one of the multitude of conductive traces of the second printed circuit.

According to one embodiment of the present invention, a method electrically connects a second printed circuit to a first printed circuit. The second printed circuit includes a first surface substantially parallel to a first plane and a second surface substantially parallel to a second plane perpendicular to the first plane. The first surface includes a first area and the second surface includes a second area smaller than the first area. The second printed circuit further includes a multitude of conductive traces formed in a layer of the second printed circuit substantially parallel to the first plane. The method includes; providing a first conductive pin including a first longitudinal axis, providing a second conductive pin including a second longitudinal axis, receiving a portion of the first conductive pin through a first notch formed in the second surface of the second printed circuit, and receiving a portion of the second conductive pin through a second notch formed in the second surface of the second printed circuit. The method further includes; installing the first conductive pin in the first notch such that the first longitudinal axis is positioned substantially parallel to the first plane, installing the second conductive pin in the second notch such that the second longitudinal axis is positioned substantially parallel to the first plane, electrically connecting the first conductive pin to a first one of the multitude of conductive traces of the second printed circuit, and electrically connecting the second conductive pin to a second one of a multitude of conductive traces of the second printed circuit.

According to another embodiment, the method further includes installing the first conductive pin in the first notch such that the first longitudinal axis is positioned substantially perpendicular to the second plane. According to another embodiment, installing the first conductive pin includes at least one of soldering, press-fitting, taping, gluing, or gluing with conductive paste into the first notch.

According to another embodiment, the method further includes overlaying an epoxy layer on a portion of the first surface adjacent the first notch and a portion of the first conductive pin. According to another embodiment, the method further includes overlaying a polyimide film including a sticky silicone adhesive on a portion of the first surface adjacent the first notch and a portion of the first conductive pin.

According to another embodiment, providing the first conductive pin includes spring-loading and partially enclosing the first conductive pin in a supporting shell adapted to install into the first notch. According to another embodiment, providing the first conductive pin includes forming a first pin width in a direction substantially perpendicular to the first longitudinal axis, forming a first end, and forming a second end located opposite the first end. The first pin width is a substantially constant value from the first end to the second end.

According to another embodiment, providing the first conductive pin includes forming a portion of the first conductive pin adjacent to a first end of the first conductive pin for installation into the first notch. Providing the first conductive pin further includes forming a second end of the first conductive pin opposite the first end, and threading a portion of the first conductive pin adjacent to the second end for receiving a nut when the second printed circuit is connected to the first printed circuit.

According to another embodiment, the method further includes providing a third conductive pin. The third conductive pin includes a third longitudinal axis. The method further includes receiving a portion of the third conductive pin through a third notch formed in the second surface of the second printed circuit. The first notch is spaced apart from the second notch at a first spacing in a first direction substantially parallel to an intersection of the first plane and the second plane. The second notch is spaced apart from the third notch at a second spacing in the first direction, the second spacing being different than the first spacing. The method further includes installing the third conductive pin in the third notch such that the third longitudinal axis is positioned substantially parallel to the first plane and electrically connecting the third conductive pin to a third one of the multitude of conductive traces of the second printed circuit.

According to another embodiment, the method further includes providing an alignment fixture. The alignment fixture includes a recess to align the first longitudinal axis substantially parallel to the first plane. The method further includes positioning the alignment fixture adjacent the first notch, receiving the first conductive pin in the recess before installing the first longitudinal axis, and aligning the first conductive pin along its first longitudinal axis substantially parallel to the first plane.

According to another embodiment, the method further includes providing the first conductive pin further including a third longitudinal axis substantially perpendicular to the first longitudinal axis. The method further includes installing a portion of the first conductive pin along its third longitudinal axis into a through-hole located within a portion of the third surface and away from the second surface and installing a portion of the first conductive pin along the first longitudinal axis in the first notch.

According to another embodiment, providing the first conductive pin includes forming the first conductive pin to include at least one bend. According to another embodiment, providing the first conductive pin further includes forming the first conductive pin to include a third longitudinal axis at an angle not less than a right-angle from the first longitudinal axis. A portion of the first conductive pin along the first longitudinal axis is installed in the first notch. A portion of the first conductive pin along the third longitudinal axis is positioned substantially not parallel to the first plane.

According to another embodiment, providing the first conductive pin includes forming a broadened region extending from a first end of the first conductive pin to a predetermined location along the first longitudinal axis to increase contact between the first notch and the first conductive pin. According to another embodiment, providing the broadened region includes bending the first conductive pin. According to another embodiment, providing the broadened region includes flattening the first conductive pin.

According to another embodiment, the method further includes coupling a third printed circuit to the second printed circuit. The third printed circuit includes a third surface substantially parallel to the first plane and a fourth surface substantially parallel to the second plane. The third surface includes a third area and the fourth surface includes a fourth area smaller than the third area. The third printed circuit includes a multitude of conductive traces formed in a layer of the third printed circuit substantially parallel to the first plane. The method further includes providing a third conductive pin including a third longitudinal axis and receiving a portion of the third conductive pin through a third notch formed in the fourth surface of the third printed circuit. The method further includes installing the third conductive pin in the third notch such that the third longitudinal axis is positioned substantially parallel to the first plane and electrically connecting the third conductive pin to a first one of the multitude of conductive traces of the third printed circuit.

According to another embodiment, attaching includes connecting at least one conductor between a corresponding one of the multitude of conductive traces of the third printed circuit to a corresponding one of the multitude of conductive traces of the second printed circuit. According to another embodiment, attaching includes disposing a thermally conducting and electrically insulating layer between the second printed circuit and the third printed circuit. According to another embodiment, attaching includes connecting a heat dissipater to the thermally conducting and electrically insulating layer. According to another embodiment, the thermally conducting and electrically insulating layer comprises a conduction via electrically connecting a corresponding one of the multitude of conductive traces of the third printed circuit to a corresponding one of the multitude of conductive traces of the second printed circuit.

According to one embodiment of the present invention, a method electrically connects a second printed circuit to a first printed circuit. The method includes forming the second printed circuit including a first surface substantially parallel to a first plane and a second surface substantially parallel to a second plane perpendicular to the first plane. The first surface includes a first area and the second surface includes a second area smaller than the first area. The method further includes forming a multitude of conductive traces in a layer of the second printed circuit substantially parallel to the first plane. The method further includes forming a first notch in the second printed circuit, the first notch including a first opening through the second surface for receiving a portion of a first conductive pin substantially parallel to the first plane through the first opening and for electrically connecting the first conductive pin to a first one of the multitude of conductive traces when a portion of a first longitudinal axis of the first conductive pin is installed in the first notch. The method further includes forming a second notch in the second printed circuit, the second notch including a second opening through the second surface for receiving a portion of a second conductive pin substantially parallel to the first plane through the second opening and for electrically connecting the second conductive pin to a second one of the multitude of conductive traces when a portion of a second longitudinal axis of the second conductive pin is installed in the second notch.

According to one embodiment of the present invention, a first electric subassembly adapted to be connected to a second electric subassembly, the first electric subassembly includes a multitude of planar bases and at least one thermally conducting and electrically insulating layer disposed between at least a first subset of the multitude of planar bases. At least one of the multitude of planar bases includes; a first surface substantially parallel to a first plane having a first area, a second surface substantially parallel to a second plane perpendicular to the first plane having a second area smaller than the first area. At least one of the multitude of planar bases further includes; a multitude of electrically conductive traces arranged in the first plane, a multitude of indentations in the second surface, and a multitude of electrical conductors each being associated with and installed in a different one of the multitude of indentations. Each of the multitude of electrical conductors is associated with and electrically connected to a different one of the multitude of electrically conductive traces. Each of the multitude of electrical conductors includes an end extending beyond the second surface.

A better understanding of the nature and advantages of the embodiments of the present invention may be gained with reference to the following detailed description and the accompanying drawings.

### DESCRIPTION OF THE DRAWINGS

FIG. 1A is a simplified side view of a common pin-strip connector.

FIG. 1B is a simplified side view of the pin-strip connector referenced in FIG. 1A mounted in through-holes on a PCB.

FIGS. 2A and 2B are simplified side views of a common edge rivet mount pin and its mounting onto a PCB, respectively.

FIG. 3A is a simplified plane view of a PCB including a multitude of notches at one edge of the PCB, in accordance with one embodiment of the present invention.

FIG. 3B is a detailed perspective view of one of the notches represented in FIG. 1, in accordance with one embodiment of the present invention.

FIG. 4A is a simplified plane view of a first module including the PCB represented in FIG. 3B including a multitude of conductive pins installed in the notches at one edge of the PCB, in accordance with one embodiment of the present invention.

FIG. 4B is a simplified plane view of the module represented in FIG. 4A mounted vertically on a main-board shown in edge view, in accordance with one embodiment of the present invention.

FIG. 4C is a simplified plane view of a module including a multitude of conductive pins installed in the notches at one edge of the PCB including multiple spacing between the notches, in accordance with one embodiment of the present invention.

FIG. 5 is a simplified side view of a module including the PCB represented in FIG. 3B including a multitude of conductive pins installed in the multitude of notches, in accordance with one embodiment of the present invention.

FIG. 6 is a simplified side view of a fixture aiding the assembly of the module represented in FIG. 4A, in accordance with one embodiment of the present invention.

FIG. 7 is a detailed perspective view of a notch in a PCB including a larger thickness than the notch thickness, in accordance with one embodiment of the present invention.

FIG. 8 is a simplified side view of a module including the PCB represented in FIG. 7 including a multitude of conductive pins installed in a multitude of notches, in accordance with one embodiment of the present invention.

FIG. 9A is a detailed perspective view of a PCB including a blind notch including a through-hole in the blind notch, in accordance with one embodiment of the present invention.

FIG. 9B is a simplified top view of a PCB including angled notches and optional through-holes in blind notches, in accordance with one embodiment of the present invention.

FIG. 10 is a simplified side view of a module including the PCB represented in FIG. 9A including a multitude of conductive pins installed in the multitude of notches, in accordance with one embodiment of the present invention.

FIG. 11 is a simplified side view of a module including the PCB similar to the PCB represented in FIG. 3B including a multitude of conductive pins installed in the multitude of notches, each conductive pin including one right angle, in accordance with one embodiment of the present invention.

FIG. 12 is a simplified side view of a module including the PCB similar to the PCB represented in FIG. 7 including a multitude of conductive pins installed in the multitude of notches, each conductive pin including one right angle, in accordance with one embodiment of the present invention.

FIG. 13 is a simplified side view of a module including the PCB similar to the PCB represented in FIG. 9A including a multitude of conductive pins installed in the multitude of notches, each conductive pin including two right angle bends, in accordance with one embodiment of the present invention.

FIGS. 14A and 14B are simplified plane and end views respectively of a module including a PCB including a restraining notch, a multitude of conductive pins and an exemplary square conductive pin installed in a multitude of notches, in accordance with some embodiments of the present invention.

FIG. 15A is a simplified plane view of a module including the PCB represented in FIG. 3B including a reinforcing film layer overlaying the multitude of conductive pins installed in the multitude of notches, in accordance with some embodiments of the present invention. FIG. 15A further includes a restraining pin installed in a notch, in accordance with another embodiment of the present invention.

FIG. 15B is a simplified side view of a spring-loaded conductive pin, in accordance with one embodiment of the present invention.

FIG. 15C is a simplified side view of a module including the PCB represented in FIG. 3B including a multitude of the spring-loaded conductive pins represented in FIG. 15B installed in the multitude of notches, in accordance with one embodiment of the present invention.

FIG. 16A and 16B are simplified views of a conductive pin including a flattened region at one end of the conductive pin, in accordance with one embodiment of the present invention.

FIG. 17 is a simplified side view of a module including the PCB represented in FIG. 3B including a multitude of conductive pins, each including the flattened region at one end of the conductive pin represented in FIG. 16A installed in the multitude of notches, in accordance with one embodiment of the present invention.

FIG. 18 is a simplified side view of a bent conductive pin, in accordance with one embodiment of the present invention.

FIG. 19 is a simplified side view of a module including the PCB represented in FIG. 3B including a multitude of bent conductive pins each represented in FIG. 18 installed in the multitude of notches, in accordance with one embodiment of the present invention.

FIG. 20 is a simplified perspective view of an assembly of a multitude of attached modules each similar to the module represented in FIG. 4C including a multitude of electrical connections between the modules, in accordance with one embodiment of the present invention.

### DETAILED DESCRIPTION

A printed circuit, hereinafter also called a printed circuit board (PCB), is a pattern comprising printed wiring formed in a predetermined design in, or attached to, the surface or surfaces of a common base. The base of a printed circuit may include an insulating planar substrate or board formed from a heat resistant resin and reinforcing fiber such as FR4, polyimide, ceramic or other insulating materials. In contrast, semiconductor material forms at least part of the base or substrate of an integrated circuit. The printed circuit may provide electrical connection and mechanical support to an integrated circuit or semiconductor chip mounted on at least one of the two component mounting surfaces of the printed circuit. A printed circuit is thus distinguished from an integrated circuit because the base of a printed circuit does not include a semiconductor material between the two component mounting surfaces of the printed circuit.

The printed wiring is a patterned conductive layer or layers on a surface of and/or within the printed circuit, so as to provide point-to-point, point-to-multipoint, point-to-ground or power plane electric connection and to make electrical connection when electrical components are mounted on a component mounting surface of the printed circuit. It is understood in describing the embodiments of the present invention that the term conductive applies to any material including electrical resistivity less than 10⁻² ohm-cm. It is understood in describing the embodiments of the present invention that the terms connect, connected, and connecting applies to making direct electrical contact between at least two conductive elements without intervening passive or active circuit elements. For example, two conductive elements may be connected by direct mechanical contact, solder, conductive glue, or other conductive material.

The combined total height of the common off-the-shelf pin-strip connector and socket may significantly limit the height available to the rest of the vertically mounted module in a low profile system, such as 1-U server chassis. Therefore, there is a need for a module connector technology that lowers the height of a module connected to a main-board while providing the keying function at minimum cost. Further, there is a need for a module to main-board connector technology that allows the module to fit into smaller spaces.

The present invention relates generally to printed circuits and in particular, to the electrical interface and coupling of one printed circuit to another. According to an embodiment of the present invention, a multitude of discrete electrically conductive pins are installed directly at a corresponding multitude of pre-fabricated notches on one edge of a PCB to form a module. The conductive pins installed in the module function as connectors, which facilitate mounting the module to a main-board and reduce the number of electrically inactive pins by combining keying and electrical connection functions.

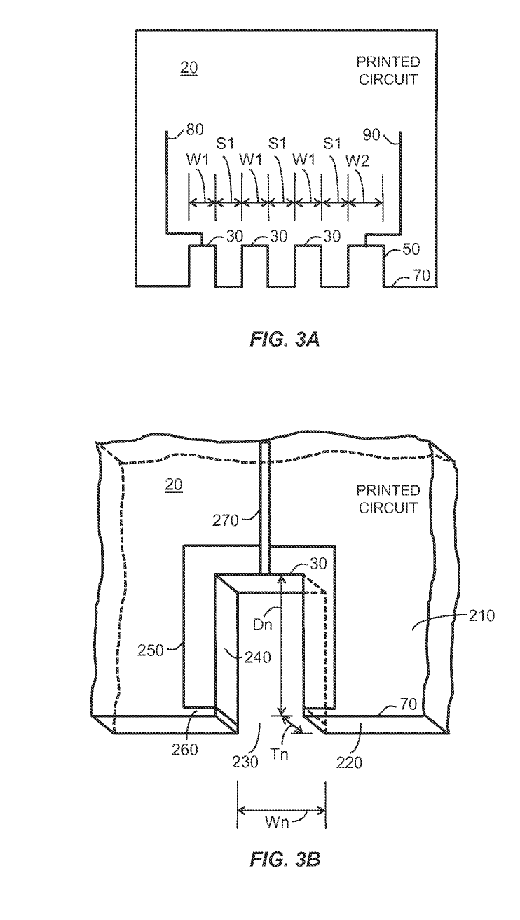

FIG. 3A is a simplified plane view of a PCB 20 including a multitude of indentations or notches 30 and a notch 50 at one edge 70 of the PCB, in accordance with a first embodiment of the present invention. PCB 20 may include a multitude of conductive traces 80 and 90 formed in a layer of PCB 20 which is substantially parallel to the component mounting surface. One of the multitude of conductive traces 80 and 90 may be on a surface of PCB 20 or may be embedded within PCB 20. Each of the multitude of conductive traces terminate adjacent to corresponding ones of the multitude of notches. The conductive traces carry power, ground, and signals to and from the notch at the edge of the PCB. PCB 20 may include single-layered printed wiring or multi-layered printed wiring. One of the multitude of conductive traces may be formed on one of the two component mounting surfaces of the PCB or on a layer embedded within the PCB.

A multitude of notches 30 are formed at edge 70 of PCB 20. In one embodiment, each one of the multitude of notches 30 includes a notch width W1 in a first direction along one edge 70 of PCB 20. In one embodiment, a notch 50 is at edge 70 of PCB 20. Notch 50 includes a notch width W2 in the first direction. In one embodiment, width W1 of notch 30 is not equal to width W2 of notch 50, to facilitate a keying function to be described below. Each one of the multitude of notches 30 is spaced apart at a spacing S1 in the first direction. In one embodiment, notch 50 is spaced apart from one of the multitude of notches 30 at the same spacing, S1. The function of the notches is to accept conductive pins corresponding to the notch width that, when attached to the PCB, enable the conductive pins to function as connectors between a module and a main board.

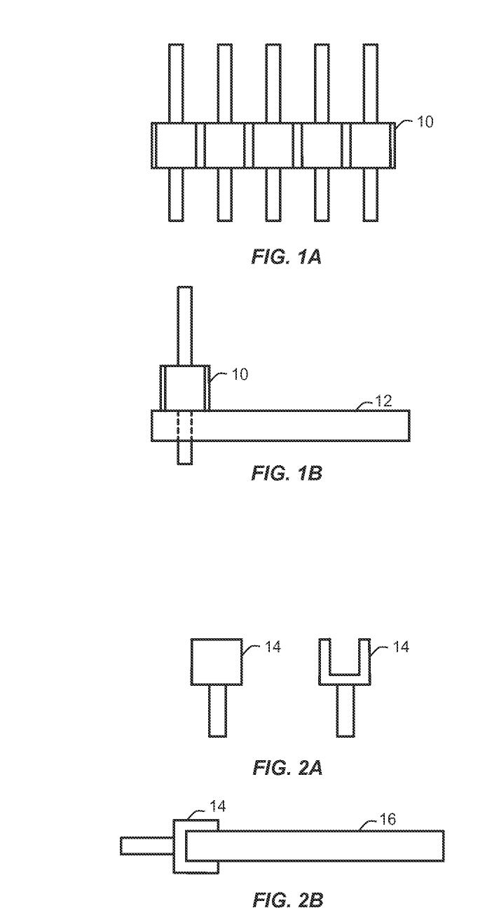

FIG. 3B is a detailed perspective view of one of the notches, for example notch 30, or for example notch 50 (not shown), represented in FIG. 3A, in accordance with one embodiment of the present invention. FIG. 3B shows PCB 20 including a component mounting surface 210 substantially parallel to a first plane (not shown). The term substantially means within the manufacturing tolerances common to PCBs. Component mounting surface 210 corresponds to one of two surfaces upon which components (not shown) may be mounted to the PCB. PCB 20 includes an edge surface 220 substantially parallel to a second plane (not shown) perpendicular to the first plane. Edge surface 220 corresponds to one edge 70 of PCB 20 referenced in FIG. 1. FIG. 3B shows component mounting surface 210 including a first area and edge surface 220 including a second area smaller than the first area, because the thickness of PCB 20 is much less than the width or depth of the PCB.

FIG. 3B further shows each one of first multitude of notches 30 including an opening 230 through edge surface 220, adapted to receive a portion of a conductive pin (not shown). Notch 30 may include a width Wn in the first direction, which is substantially parallel to an intersection of the first plane and the second plane. Notch 30 may include a thickness Tn in a direction substantially perpendicular to the first plane. Notch 30 may include a depth Dn in a second direction substantially perpendicular to the second plane. Notch 30 may include a sidewall 240, which is not parallel to the first plane. In one embodiment, a portion of sidewall 240 may be overlaid by a sidewall conductive layer. The material forming the sidewall conductive layer may be copper or other metal common to printed wiring or similar to conductive composite materials. In one embodiment, PCB 20 includes a thickness equal to the notch thickness Tn and the notch is cut entirely through the PCB.

In one embodiment, the entire surface of the sidewall 240 may be overlaid by the sidewall conductive layer. In one embodiment, a surface conductive layer 250 may overlay a portion of component mounting surface 210 adjoining one of the multitude of notches 30. In one embodiment, the sidewall conductive layer or the surface conductive layer regions may be spaced away from edge surface 220 by a few mils, represented by a gap 260 to prevent metal smearing during the board outline routing or edge chamfering fabrication processes of PCB 20. In one embodiment, the sidewall conductive layer or the surface conductive layer regions may be formed adjoining the edge surface 220 or overlaying a portion of edge surface 220 by one to ten mils adjacent to notch 30, to improve soldering of the conductive pin to the notch during module assembly. A conductive trace 270 corresponding to one of the multitude of conductive traces 80 and 90 referenced in FIG. 3A is shown in FIG. 3B terminating at the edge of notch 30. The surface conductive layer and/or the sidewall conductive layer regions in any combination may be electrically connected to conductive trace 270.

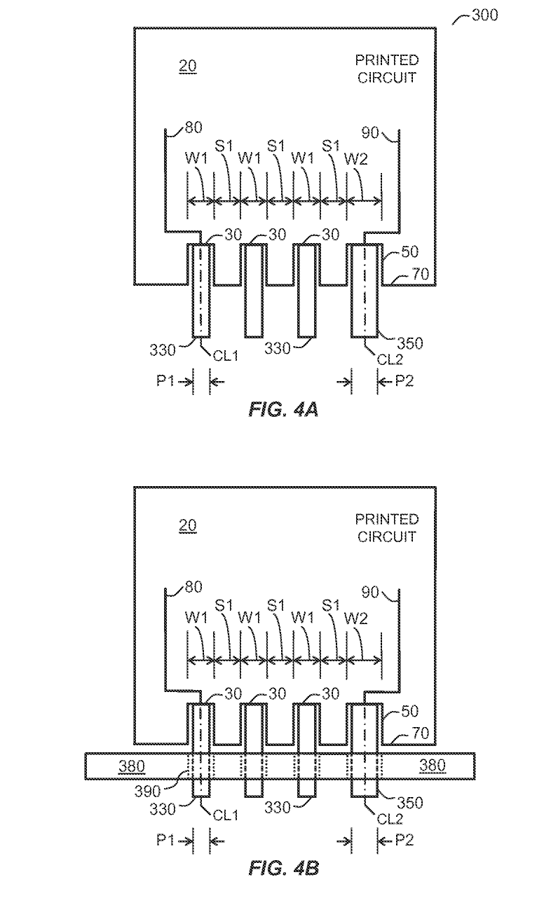

FIG. 4A is a simplified plane view of a first module 300 including PCB 20 represented in FIG. 3B including a multitude of conductive pins 330 and 350 installed in notches 30 and 50, respectively, in accordance with one embodiment of the present invention. FIG. 4A shows PCB 20 including the same embodiments as shown in FIG. 3A and FIG. 3B. Further, FIG. 4A shows each one of the multitude of notches 30 and 50 including openings adapted to receive a conductive pin 330 and a conductive pin 350, respectively. Each one of the multitude of notches 30 and 50 may be adapted to electrically connect corresponding ones of the multitude of conductive pins to corresponding ones of the multitude of conductive traces 80 and 90. Each of the multitude of conductive pins 330 and 350 includes a longitudinal axis CL1 and CL2, respectively. Each of the multitude of conductive pins 330 and 350 are installed in their respective notches such that their respective longitudinal axes are positioned substantially parallel to the first plane. In one embodiment, each of the multitude of conductive pins is installed in notch 30 such that its longitudinal axis is positioned substantially perpendicular to the second plane.

FIG. 4B is a simplified plane view of module 300 represented in FIG. 4A mounted vertically on a main-board 380 shown in edge view, in accordance with one embodiment of the present invention. Thus, the multitude of conductive pins installed in corresponding ones of the multitude of notches 30 and 50, may electrically connect PCB 20 to main-board 380. Module 300 may be mounted into a corresponding pin strip connector socket attached on a main-board for a removable module to main-board mounting. Alternatively, conductive pins 330 and 350 may be soldered directly into through-holes 390 on main board 380 to mount the module to the main-board. The conductive pins form a multitude of electrical connections at the edge of module 300, which provide conductive paths for connecting power, ground, and signals from the main-board to module 300.

Unlike prior art solutions, the conductive pins and notches in module 300 eliminate the significant cost added to the module when a prefabricated, off-the-shelf pin-strip connector or socket is included. Further, module 300 enables the module to be mounted closer to the main-board's component surface than would be possible in common vertical mounting due to the combined height required by using a prefabricated pin-strip connector plus its respective socket on the main-board. Module 300 thus provides a smaller module plus socket combined height to fit into systems requiring smaller form factors. Further, module 200 is custom designed or fabricated without the spacing constraints of commonly provided pin-strip connectors, edge connectors, or mezzanine connectors, thus saving further space.

The conductive pins 330 and 350 are not mechanically coupled until the conductive pins are installed in corresponding ones of the multitude of notches in the module. In other words, the conductive pins are discrete pins, in contrast to the common pin-strip connector wherein all the pins include equal geometry and are held together at a uniform spacing by the pin-strip connector's plastic housing. In contrast to common pin-strip connectors, in one embodiment, conductive pin 330 does not include an insulating sleeve surrounding conductive pin 330. In contrast to common board edge rivet mount pins and pins with a metal ferrule insertion stop, in one embodiment, conductive pin 330 may include a first end and a second end located opposite the first end. The pin width P1 is a substantially constant value along longitudinal axis CL1 from the first end to the second end, which simplifies conductive pin manufacture and lowers cost. The conductive pins do not need metal ferrule or plastic housing insertion stops surrounding each conductive pin because the notch depth Dn, referenced above in FIG. 3B, determines how deep the conductive pins are inserted into the PCB of the module. Referring again to FIG. 4A, because conductive pins 330 and 350 are discrete, they are simpler and thus lower in cost than pin-strip connectors. Further, because conductive pins 330 and 350 are discrete and free of insulating housings or metal ferrules, it is easier to adjust their length with low-cost manufacturing techniques than with off-the-shelf conducting pins. In-turn, the pin lengths of conductive pins 330 and 350 may be shorter than off-the-shelf connectors, thus providing module area savings and/or enabling the module to fit in a smaller space, than possible with commonly provided conducting pins.

Because conductive pins 330 and 350 are discrete pins, an advantage offered by module 300 over the prior art is the flexibility to form an asymmetric geometry in the multitude of conductive pins to take the place of the commonly provided excess keying pin. Recall, the keying pin is provided to orient the module properly when mounted on the main-board. For example, conductive pin 350 may include a different mechanical shape or geometry than conductive pin 330. Such mechanical geometry difference functions as an identification mechanism that may be built into module 300 to differentiate one mounting orientation from another or identify different types of modules in a system. Thus, an identification mechanism is built into the module to; i) maintain proper insertion orientation into the main-board, or ii) prevent inserting the wrong module into the main-board, without losing electrical function of any conductive pins.

Further, unlike the commonly provided excess keying pin, which may not carry an electrical signal or power, conductive pin 350 may carry any of the same types of electrical signals as are carried by conductive pins 330. For example, conductive pin 350 may connect power, ground, or signals between the main-board and module 300, while simultaneously providing mechanical orientation keying. Thus, because conductive pin 350 provides keying information and simultaneously carries electrical signals, mounting connector area may be saved over commonly provided pin-strip connectors.

Each one of the multitude of conductive pins 330 may include a pin width P1 in a direction substantially perpendicular to longitudinal axis CL1. Conductive pin 350 includes a pin width P2 in a direction substantially perpendicular to longitudinal axis CL2. In one embodiment, for conductive pins including the same cross-sectional geometry in a direction perpendicular to longitudinal axis CL1, one of the multitude of conductive pins 330 includes a pin width P1 that is substantially equal to the pin width of another one of the multitude of conductive pins 330, in which case the keying function may be facilitated by providing asymmetric or different pin spacing as described above. Cross-sectional geometry may include shapes such as circular, square, rectangular, triangular, and so on, each shape having corresponding cross-sectional area. Conductive pins having the same cross-sectional geometry have the same cross-sectional shape and have the same cross-sectional area.

In one embodiment, conductive pin 350 includes pin width P2 that is greater than pin width P1 of one of the multitude of conductive pins 330, where the multitude of conductive pins 330 have the same cross-sectional shape as conducting pin 350. This difference in pin width provides an asymmetry for keying the mounting of the module to the main-board. The wider pin width P2 of conductive pin 350 is accommodated by a correspondingly wider receiving socket or through-hole on the main-board than the narrower socket or through-hole normally provided for conductive pin 330 including smaller width P1. The keying function is obtained because conductive pin 350 will not fit into the receiving socket for conductive pin 330 when an attempt is made to mount, in reverse orientation, the multitude of conductive pins to the main board. Analogously, in another embodiment, pin width P2 may instead be smaller than pin width P1, then P1 would not fit into a receiving socket or through-hole on the main-board designed to accept the smaller pin width P2. Therefore the keying function is facilitated when P2 is different than or not equal to P1. Thus, module 300 will mount in a predetermined orientation on the main-board.

While the width of the notches generally corresponds to the width of the conductive pins, a slightly larger notch width, typically a few mils larger than the width of the corresponding conductive pin could make the module assembly easier. For example, W1 may be a few mils larger than P1. Similarly, W2 may be a few mils larger than P2.

In one embodiment, where the multitude of conductive pins 330 have different cross-sectional shape than conducting pin 350, conductive pin 330 includes a first cross sectional area substantially perpendicular to longitudinal axis CL1 and conductive pin 350 includes a second cross sectional area substantially perpendicular to longitudinal axis CL2. The second cross sectional area may be different than or not equal to the first cross sectional area to facilitate the keying function, irrespective of symmetrical notch spacings Sn, pin widths Pn, or notch widths Wn. In one embodiment, the second cross-sectional area is larger than the first cross sectional area such that the conductive pin having the second cross sectional area may not mechanically fit into a through-hole or socket provided on the main-board for the conductive pin having the first cross sectional area, when the module is mounted on the main-board. In one embodiment, the keying function is provided by the asymmetry between the first cross sectional area and the second cross sectional area, while keeping P1 equal to P2, W1 equal to W2, and the notches spaced at the same spacing S1, which simplifies PCB manufacture. For example, a multitude of conductive pins 330 all include a round cross-sectional shape with 25-mil diameter or width and conductive pin 350 includes a square cross-sectional shape with the same 25-mil width per side. The multitude of conductive pins 330 and conductive pin 350 may be received into corresponding notches 30 all having the same notch width Wn equal to about 30-mil. However, the 25-mil square conductive pin may not be inserted into a through-hole on the main-board matched to receive the 25-mil round conductive pin because the square pin includes greater cross sectional area than the round pin. A minimum through-hole size of 36-mil in diameter is required to receive the 25-mil square conductive pin. The square conductive pin may thus serve as the keying pin.

Conductive pins 330 and 350 may provide electrical connection as well as mechanical support for the mounting of module 300 to the main-board. Although conductive pins formed of copper provide a cheap conductive solution they may not provide sufficient mechanical strength to maintain the module in the desired position on the main-board. Stronger mounting than copper may be provided by selecting the conductive pins from materials such as brass alloy 360½ hard, brass alloy 360¼ hard, phosphor bronze alloy 544, tellurium copper alloy 145, or conductive carbon composite.

Although FIG. 3B described notch 30, notch 50 referenced in FIG. 3A and FIG. 4A may share many of the same embodiments as notch 30 described in reference to FIG. 3B except width W2 of notch 50 is different than width W1 of notch 20. In one embodiment, notch 50 may include a larger depth Dn than notch 30 to provide greater mechanical support to conductive pin 350 referenced in FIG. 4A. Referring to both FIG. 3B and FIG. 4A, the sidewall conductive layer region or surface conductive layer region 250 may facilitate installation of the conductive pins. In one embodiment, conductive pin 330 may be installed by being soldered, press-fit, taped, glued, or glued with conductive paste into a corresponding one of the multitude of notches 30 or by any combination of those techniques. The sidewall conductive layer or surface conductive layer regions may increase the amount of solder around the conductive pin at the notch to increase the mechanical strength of the installation.

FIG. 4C is a simplified plane view of a second module 400 including a PCB 420 similar to the PCB represented in FIG. 3B including a multitude of conductive pins 330 and 450 installed in notches 30 and 430, respectively, at one edge 470 of PCB 420 including multiple spacing S1 and S2 between the notches, in accordance with one embodiment of the present invention. Each one of the first multitude of notches 30 may be spaced apart at a spacing S1 in the first direction substantially parallel to an intersection of the first plane and the second plane.

Because the conductive pins are discrete, the notch locations along one edge 470 of PCB 420 are flexible and not restricted to uniform spacing. Thus, keying function may be facilitated by asymmetric notch position instead of, or in combination with, conductive pin geometry asymmetry. Module 400 is similar to module 300 referenced in FIG. 4A except in module 400, as shown in FIG. 4C, notch 430 may be spaced apart from one of the multitude of notches 30 at a spacing S2 in the first direction. Spacing S2 may be different than the spacing S1, providing the asymmetry to facilitate the keying function. Further, the multitude of conductive pins 330 and 450 include the same pin width and are received by the multitude of notches 30 and 430 each including the same notch width W1, which simplifies module manufacturing and lowers cost. The sockets or through holes on the mother board may be positioned corresponding to the asymmetrical conductive pin locations in module 400 to facilitate the keying function.

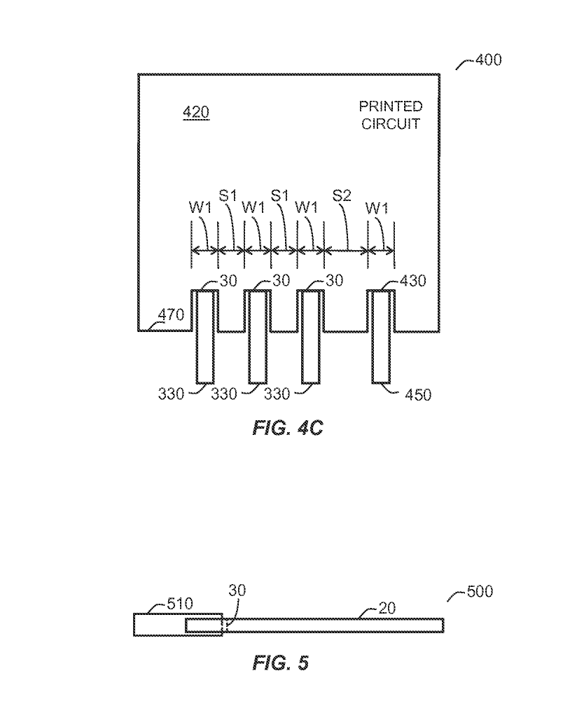

FIG. 5 is a simplified side view of module 500 including the PCB represented in FIG. 3B including a multitude of conductive pins 510 installed in the multitude of notches 30, in accordance with one embodiment of the present invention. FIG. 5 shows the side view width of conductive pin 510 to be wider than the thickness of PCB 20 and notch 30 being cut entirely through the thickness of the PCB. Thick conductive pin width may improve the strength of soldering to the PCB and the mounting to the main-board. Alternatively, in one embodiment the conductive pin may include a width that is smaller than the thickness of the PCB.

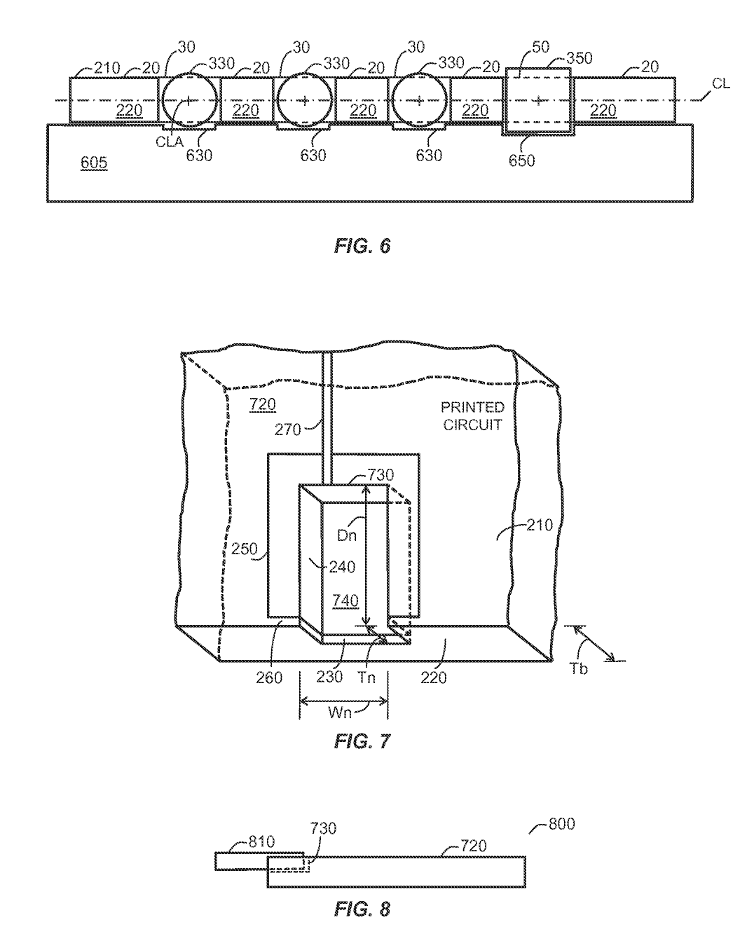

FIG. 6 is a simplified side view of a fixture 605 aiding the assembly of the module represented in FIG. 4A, in accordance with one embodiment of the present invention. Alignment fixture 605 includes a recess 630, if the vertical cross-section width of conductive pins 330 and/or 650 is larger than the thickness of PCB 20, to align longitudinal axis CLA of conductive pin 330 substantially parallel to the first plane. Recess 630 may be adapted to align longitudinal axis CLA a predetermined distance from component mounting surface 210.

During manufacture of the module, the PCB is formed including the multitude of conductive traces and the multitude of notches in the PCB. Conductive alignment fixture 605 may be provided as described above. Recess 630 is provided if needed to align pin longitudinal axis CLA with module centerline CL. The alignment fixture may be positioned under one of the multitude of notches and large enough to hold the multitude of conductive pins in place. A conductive pin may be received in the recess of fixture 605 while a portion of the conductive pin is received through the opening in the notch, aligning longitudinal axis CLA substantially parallel to the first plane or the component mounting surface. The notch aligns the conductive pin such that longitudinal axis CLA is substantially perpendicular to the edge surface 220. The conductive pin is then installed using the techniques described above so that the conductive pin is electrically connected to one of the multitude of conductive traces, which is adjacent to the notch.

FIG. 7 is a detailed perspective view of a notch 730 in a PCB 720 including a larger thickness Tb than notch thickness Tn, in accordance with one embodiment of the present invention. Thickness is in a direction substantially perpendicular to the first plane FIG. 7 shows PCB 720 the same embodiments as PCB 20 shown in FIG. 3A and FIG. 3B except, as shown in FIG. 7, PCB 720 is thicker than the notch. Notch 730 includes a notch surface 740 substantially parallel to the first plane. Notch 730 may be called a blind notch because notch 730 does not completely cut through the entire PCB thickness. Notch surface 740 may provide additional mechanical strength to support a conducive pin installed therein, and may facilitate alignment of the longitudinal axis of the conducive pin substantially parallel to the first plane during the manufacture of the module. In one embodiment, a portion of notch surface 740 may be overlaid by a conductive layer (not shown). For example, the sidewall conductive layer over a portion of notch surface 740 may increase the amount of solder around the conductive pin at the notch to increase mechanical strength and/or reduce resistance of the conductive pin to notch installation. In one embodiment, the entire surface of notch surface 740 may be overlaid by the conductive layer (not shown). Thus, notch surface 740 may provide additional electrical contact area between one of the multitude of conductive traces 270 and the conducive pin installed in blind notch 730.

In one embodiment, notch opening 230 in edge surface 220 need not be substantially rectangular cut as is shown in the FIG. 7. In one embodiment, opening 230 need not be adjoining one of the component mounting surfaces. In one embodiment opening 230 may include a substantially circular shape, and blind notch 730 is a drill hole in edge surface 220, the drill hole includes a longitudinal axis aligned in a direction substantially perpendicular to the second plane, i.e. substantially perpendicular to edge surface 220. In one embodiment blind notch 730 may be a recess in edge surface 220, the recess including a longitudinal axis aligned in a direction substantially parallel to the first plane. In one embodiment, blind notch 730 may be surrounded by PCB 720 on all sides except for its opening 230.

FIG. 8 is a simplified side view of a module 800 including PCB 720 represented in FIG. 7 including a multitude of conductive pins 810 installed in a multitude of notches 730, in accordance with one embodiment of the present invention.

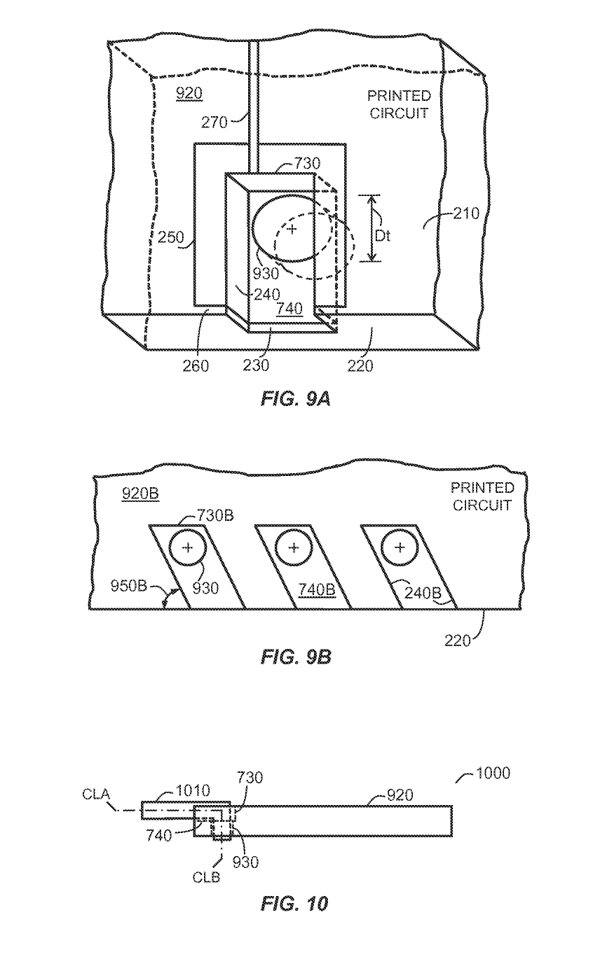

FIG. 9A is a detailed perspective view of a PCB 920 including blind notch 730 including a through-hole 930 in the blind notch, in accordance with one embodiment of the present invention. FIG. 9A shows PCB 920 including the same embodiments as PCB 720 shown in FIG. 7 except, as shown in FIG. 9A, through-hole 930 may be located within a portion of third surface 740 in blind notch 730 and located away from edge surface 220. The center of through-hole 930 may be preferably located substantially on a notch centerline substantially midway between a pair of substantially parallel notch sidewalls 240. Through-hole 930 may include a diameter Dt, which preferably is substantially similar to notch width Wn referenced in FIG. 7. In one embodiment, through-hole 930 includes a sidewall plated with a conductive material.

FIG. 9B is a simplified top view of a PCB 920B including angled notches 730B and optional through-holes 930 in blind notches, in accordance with one embodiment of the present invention. The notch sidewalls need not be substantially orthogonal to edge surface 220. Instead, each of the multitude of notches may include a pair of notch sidewalls 240B that are substantially parallel and that may intersect edge surface 220 at a substantial angle 950B other than a right angle, such as 80 degrees, 60 degrees and so on. The angled notch provides mechanical alignment and increases support for each conductive pin in the direction substantially parallel to the first plane. Forming the notch angled to edge surface 220 increases contact area between the notch and the conductive pin, thereby improving mechanical support, while preventing the notch from encroaching further into the component mounting surface area of the module to lower the height of an assembled module. The angled sidewall or notch embodiment may be combined with a conductive pin having at least one bend to position the portion of the pin outside the notch substantially perpendicular to the intersection of the first and second planes. In another embodiment, the at least one bend may position the portion of the pin outside the notch substantially perpendicular to the second plane. The angled notch embodiment may be combined with any of the embodiments described above such as the notch, blind notch, or through-hole as shown in FIGS. 2, 7, and 9 respectively.

FIG. 10 is a simplified side view of module 1000 including PCB 920 represented in FIG. 9A including a multitude of conductive pins 1010 installed in a multitude of notches 730, in accordance with one embodiment of the present invention. Through-hole 930 may be adapted to receive one of the multitude of conductive pins 1010. Unlike the conductive pins described above, which are substantially straight, one of the multitude of conductive pins 1010 further includes a substantially right angle bend between a longitudinal axis CLB and a longitudinal axis CLA. Longitudinal axis CLB may be substantially perpendicular to longitudinal axis CLA. A portion of one of the multitude of conductive pins 1010 along longitudinal axis CLB is installed in through-hole 930. A portion of one of the multitude of conductive pins 1010 along longitudinal axis CLA may be installed in blind notch 730 or at third surface 740. Through-hole 930 provides additional surface area, i.e. for soldering or other contact support, between the conductive pin and PCB 920, which further strengthens the installation of the conductive pins to the PCB. Further, through-hole 930 provides additional alignment of the conductive pins during assembly of the module.

Further, blind notch 730 and respective through-hole 930 diameter Dt may be adapted to receive the cross-section of conductive pins 1010 including various embodiments described for conductive pins 330 and 350 above and referenced in FIGS. 3-6. For example, diameter Dt may be adapted to receive conductive pins of various shapes or sizes to facilitate the keying functions described above. Analogously, PCB 920 may be formed including notches 730 and respective through-holes 930 spaced at similar spacing or spaced at different spacing to facilitate the keying functions described above, in any combination.

Embodiments of the present invention such as notches, blind-notches, or through holes may cause breakage of the base or substrate of the printed circuit if made from single crystal materials, i.e. single crystal silicon, commonly provided for semiconductor substrates. In contrast, materials provided for the base of printed circuits, such as FR4, polyimide, or ceramic, to name only a few, may be formed with notches, blind-notches, or through-holes with less risk of breakage than single crystal materials such as semiconductor substrates formed with such features.

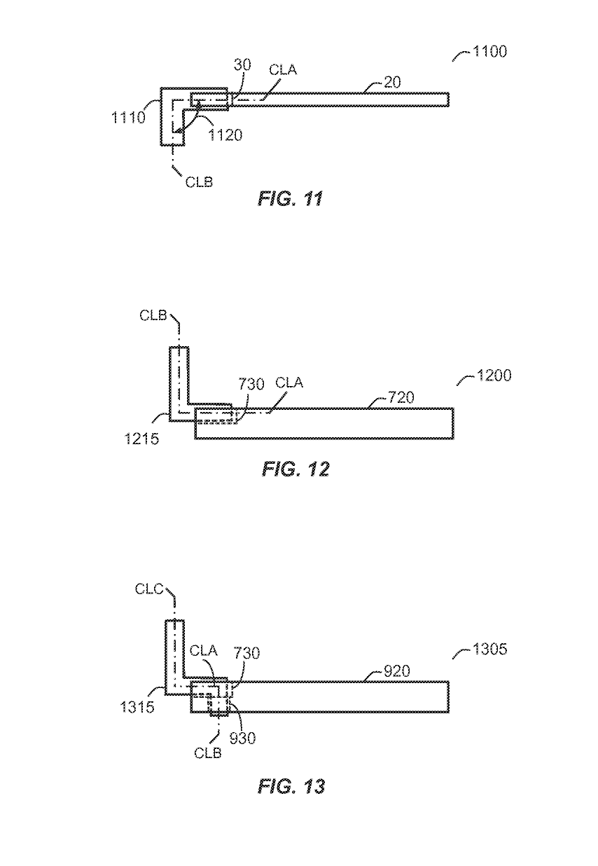

The embodiments described above may be modified such that the multitude of conductive pins include an additional substantially right-angle bend as shown in FIGS. 11-13 described below. The additional substantially right-angle bend provides mezzanine, or horizontal, mounting of the module to the main board, while preserving the benefits of the previously described embodiments including keying functions using pin width, shape or spacing, or for either buried or non-buried notches, in any combination.

FIG. 11 is a simplified side view of module 1100 including PCB 20 similar to PCB 20 represented in FIG. 3B including a multitude of conductive pins 1110 installed in the multitude of notches 30, each conductive pin including one right angle, in accordance with one embodiment of the present invention. One of the multitude of conductive pins 1110 includes a substantially right angle bend between a longitudinal axis CLB and a longitudinal axis CLA. Longitudinal axis CLB may be substantially perpendicular to longitudinal axis CLA. A portion of one of the multitude of conductive pins 1110 along longitudinal axis CLA is installed in notch 30. A portion of conductive pin 1110 along longitudinal axis CLB is positioned substantially not parallel to the first plane or pointing outwards from the component mounting surface. The right angle bend in the multitude of conductive pins provides the component mounting surface of the module to be mounted substantially parallel to the component mounting surface of the main-board, also called a horizontal mounting. The right angle bend provides a pin that may be installed in the angled notches shown in FIG. 9B. The horizontal mounting embodiment may be combined with any of the embodiments described above that facilitate the keying function, or for either buried with or without through-holes, non-buried, or angled notches embodiments, in any combination.

In another embodiment, the multitude of conductive pins may be formed with a bend at a predetermined angle 1120 between longitudinal axis CLB and longitudinal axis CLA not limited to a right angle, and preferably at an angle greater than a right angle, to mount the module to the main-board at the predetermined angle. Mounting the module to the main-board at the predetermined angle lowers the total vertical height of the module on the main-board helping the module fit into low-profile systems. The angled mounting embodiment may be combined with any of the embodiments described above that facilitate the keying function, or for either buried with or without through-holes, non-buried, or angled notches embodiments, in any combination.

FIG. 12 is a simplified side view of a module 1200, including PCB 720 similar to PCB 720 represented in FIG. 7 including a multitude of conductive pins 1215 installed in the multitude of blind notches 730, where each conductive pin includes one right angle, in accordance with one embodiment of the present invention. The features of the embodiment shown in FIG. 12 combine the features referenced in FIG. 8 and FIG. 11 including a bend in the conductive pins. Each one of the multitude of conductive pins 1215 may correspond to one of the multitude of conductive pins 1110 referenced in FIG. 11. However, FIG. 12 shows the multitude of conductive pins 1215 installed in blind notches 730 in PCB 720. One of the multitude of conductive pins 1215 include a first end on longitudinal axis CLA installed in blind notch 730 and a second end on longitudinal axis CLB opposite the first end, the second end positioned outside blind notch 730. A portion of longitudinal axis CLA or the entire length of longitudinal axis CLA may be positioned within notch 730. The second end of one of the multitude of conductive pins 1215 may be positioned such that the blind notch side of PCB 720 faces or is toward the main-board when module 1200 is mounted on the main-board. In another embodiment, the second end of one of the multitude of conductive pins 1215 may be positioned such that the blind notch side of PCB 720 faces away from or is opposite the main-board when module 1200 is mounted on the main-board. The blind notch either facing toward or facing away from the main-board embodiments may be combined with any of the embodiments described above that facilitate the keying function, for either horizontal or angled mounting, or for either buried with or without through-holes, non-buried, or angled notches embodiments, in any combination.

FIG. 13 is a simplified side view of a module 1300 including PCB 920 similar to PCB 920 represented in FIG. 9A including a multitude of conductive pins 1315 installed in the multitude of notches 730, each conductive pin including two right angle bends, in accordance with one embodiment of the present invention. The features of the embodiment shown in FIG. 13 combine the features referenced in FIG. 10 and FIG. 11, including two bends in each one of the multitude of conductive pins. FIG. 13 shows the multitude of conductive pins 1315 installed in blind notches 730 and through-holes 930 in PCB 920. One of the multitude of conductive pins 1315 include a substantially right angle bend between a longitudinal axis CLB and a longitudinal axis CLA. In one embodiment, a longitudinal axis CLC may be substantially perpendicular to longitudinal axis CLA and the bend between longitudinal axis CLC and longitudinal axis CLA may be a substantially right angle bend. In another embodiment, a longitudinal axis CLC may be at a predetermined angle to longitudinal axis CLA and the bend between longitudinal axis CLC and longitudinal axis CLA may be at the same predetermined angle, not limited to a right angle, to mount the module to the main-board at a desired angle.

One of the multitude of conductive pins 1315 include a longitudinal axis CLA installed in blind notch 730, a first end on longitudinal axis CLB installed in through hole 930, and a second end on longitudinal axis CLC opposite the first end positioned outside blind notch 730 and through hole 930. A portion of longitudinal axis CLA or the entire length of longitudinal axis CLA may be positioned within notch 730. The second end of one of the multitude of conductive pins 1315 may be positioned such that the blind notch side of PCB 920 faces or is toward the main-board when module 1300 is mounted on the main-board. In another embodiment, the second end of one of the multitude of conductive pins 1315 may be positioned such that the blind notch side of PCB 920 faces away from or is opposite the main-board when module 1300 is mounted on the main-board. The conductive pin with two bends embodiments may be combined with any of the embodiments described above that facilitate the keying function, for blind notch either facing toward or facing away from the main-board, for either horizontal or angled mounting, or for either buried or angled notches embodiments, in any combination.

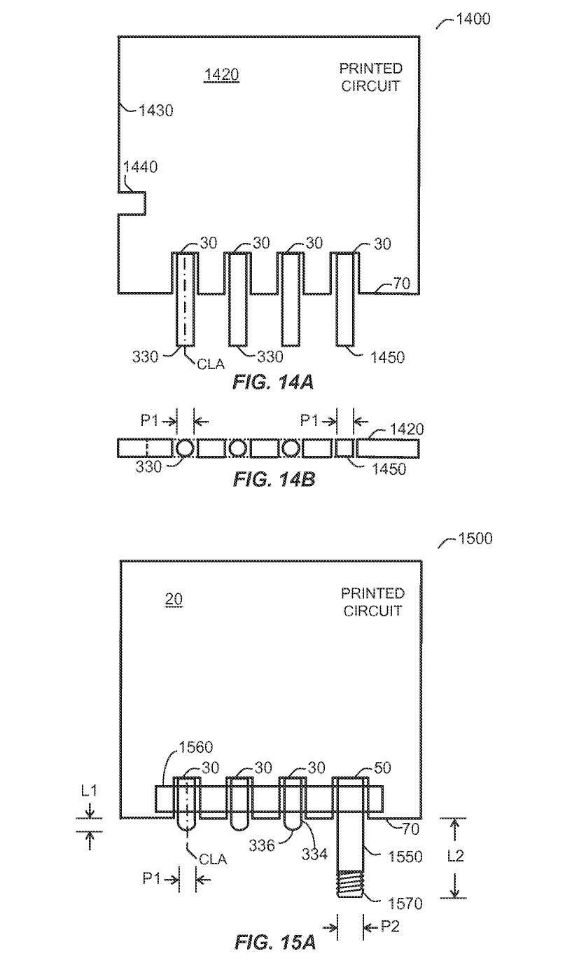

FIGS. 14A and 14B are simplified plane and end views respectively of a module 1400 including a PCB 1420 including a restraining notch 1440, a multitude of conductive pins 330 and an exemplary square conductive pin 1450 installed in a multitude of notches 30, in accordance with some embodiments of the present invention. In one embodiment, PCB 1420 is similar to PCB 20 represented in FIG. 3B, except as shown in FIG. 14A the notches in PCB 1420 are symmetric. The multitude of conductive pins 330 each has a substantially circular cross section having a diameter P1. Square conductive pin 1450 has substantially the same pin width P1 but larger cross-sectional area adapted to fit the symmetrical notches while facilitating the keying function as described above.

FIG. 14A further includes a restraining notch 1440, in accordance with another embodiment of the present invention. PCB 1420 includes a side surface 1430 substantially parallel to a third plane substantially perpendicular to the first plane and to the second plane. In other words, PCB 20 may include another edge adjacent and substantially perpendicular to edge 70. When module 1400 is detachably mounted to the main-board, there may be at least one restraining notch 1440 including an opening at side surface 1430. Restraining notch 1440 may be adapted to engage with a clip or hook attached to the main-board, when module 1400 is connected to the main-board. The clip or hook may engage in the notch to prevent module 1400 from being dismounted off the main-board unless the clip or hook is first disengaged from restraining notch 1440. The restraining notch embodiment may be combined with any of the embodiments described above that facilitate the keying function for either vertical, horizontal, or angled mounting, for either buried with or without through-holes, non-buried, or angled notches, or for the blind notch either facing toward or facing away from the main-board embodiments, in any combination.

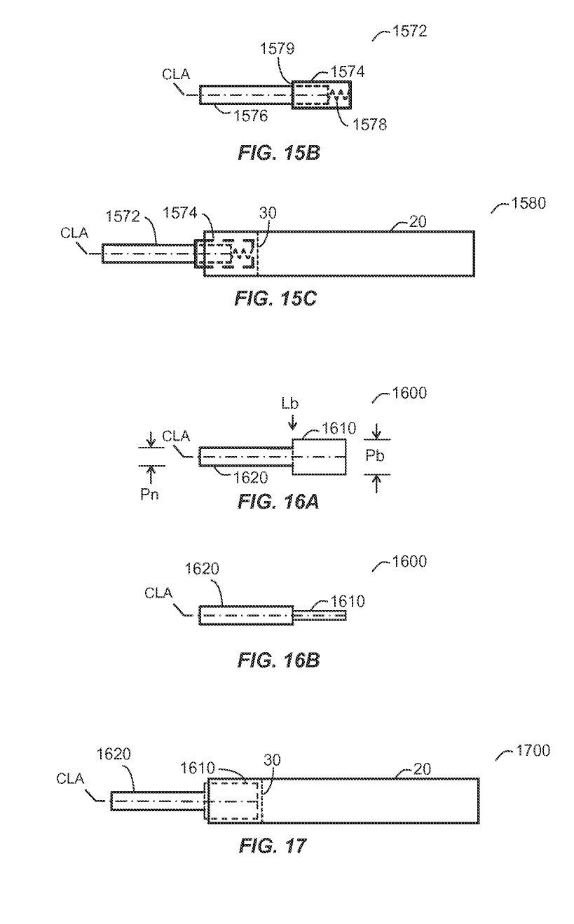

FIG. 15A is a simplified plane view of a module 1500 including PCB 20 represented in FIG. 3B including an electrically insulating reinforcing film layer 1560 overlaying the multitude of conductive pins 330 and 1550 installed in the multitude of notches 30 and 50, in accordance with some embodiments of the present invention. Reinforcing film layer 1560 may be an epoxy or a polyimide film layer, which may provide mechanical reinforcement or support to the installation of the conductive pins at the notches, thus preventing unwanted dislocation or detachment of the conductive pins during subsequent thermal cycles, such as during the solder reflow when the module is mounted on the main-board.

In one embodiment, reinforcing film layer 1560 may be an electrically insulating epoxy film layer, which overlays a portion of the component mounting surface adjacent the multitude of notches 30 and 50 and overlays a portion of each of the multitude of conductive pins 330 and 1550 after installing the multitude of conductive pins at the multitude of notches. For example, the epoxy film layer may be a low-temperature curing epoxy such as Loctite 3128™, manufactured by the Henkel Corporation, which cures in 20 minutes at 80 degrees C., if such an epoxy dispensing step is desired.

Alternatively, in one embodiment, reinforcing film layer 1560 may be a thermally conducting, electrically insulating polyimide film layer overlaying a portion of the component mounting surface adjacent the multitude of notches 30 and 50 and overlaying a portion of each of the multitude of conductive pins 330 and 1550. The polyimide film layer may include a sticky silicone adhesive to attach the polyimide film to the module. For example, the polyimide film layer may be Kapton® FIN film made by DuPont™ including a silicone adhesive. The reinforcing film layer embodiments may be combined with any of the embodiments described above that facilitate the keying or restraining notch functions, for either vertical, horizontal, or angled mounting, for either buried with or without through-holes, non-buried, or angled notches, or for the blind notch either facing toward or facing away from the main-board embodiments, in any combination.

In contrast, in one embodiment, an electrically conductive epoxy layer may be an alternative to attaching the conductive pin to the notch to press-fit or glue the conductive pin into one of the multitude of notches, provided that the conductive paste does not short circuit adjacent conductive pins between the notches

FIG. 15A further includes a restraining pin 1550 installed in notch 50 of PCB 20, in accordance with another embodiment of the present invention. Restraining pin 1550 may be conductive or non-conductive. A portion of restraining pin 1550 adjacent a first end is adapted for installation into notch 50, similar to the embodiments described above. A portion of restraining pin 1550 adjacent a second end opposite the first end may include threads 1570 adapted to receive a nut (not shown) when module 1500 is connected to the main-board. Restraining pin 1550 may be inserted into a through-hole in the main-board so that threads 1570 protrude through the side opposite the module side of the main-board when module 1500 is mounted to the main-board. Then the nut, which is larger than the through-hole may engage with threads 1570 to prevent module 1500 from being dismounted off the main-board unless the nut is first disengaged from threads 1570. The multitude of conductive pins 330 installed in the multitude of notches 30 includes a length L1 extending beyond the edge surface 70 and outside the multitude of notches 30. In contrast, restraining pin 1550 installed in one of the multitude of notches 30 includes a length L2 extending beyond edge surface 70 and outside notch 30. Length L2 is different than, and preferably greater than length L1. Restraining pin 1550 may include wider pin width P2 than the pin width P1 of the other conductive pins as shown. Alternatively, restraining pin 1550 may include the same pin width as the other conductive pins installed in the module. The restraining pin embodiment may be combined with any of the embodiments described above that facilitate the keying function or restraining notch functions, for either vertical, horizontal, or angled mounting, for either buried with or without through-holes, non-buried, or angled notches, for the blind notch either facing toward or facing away from the main-board, or for the reinforcing film layer embodiments, in any combination.

FIG. 15A further includes a conductive pin 334 including a blunt tip 336, in accordance with another embodiment of the present invention. A portion of conductive pin 334 adjacent to a first end is installed in notch 30; and a second end opposite the first end includes a substantially blunt tip 336. The substantially blunt tip may be roughly hemispherical or roughly ellipsoidal so as to prevent puncture damage if the module to main-board mounting includes an anisotropic conducting layer between blunt tip 336 and the main board. The anisotropic conducting layer provides electrical conduction in the direction substantially perpendicular to the surface of the layer, while providing little conduction in the direction substantially parallel to surface. In one embodiment, the pin length L1 outside the notch may be shortened, providing the blunted portion of the conductive pin extends beyond the notch sufficiently to make proper electrical contact to a land pattern on the main-board when the module is mounted thereto. The blunt tip embodiment may be combined with any of the embodiments described above that facilitate the keying function or restraining notch or pin functions, for either vertical, horizontal, or angled mounting, for either buried with or without through-holes, non-buried, or angled notches, for the blind notch either facing toward or facing away from the main-board, or for the reinforcing film layer embodiments, in any combination.

FIG. 15B is a simplified side view of a spring-loaded conductive pin 1572, in accordance with one embodiment of the present invention. Spring-loaded conductive pin 1572 may include a supporting shell 1574 shaped and adapted to enclose a portion of a conducting pin 1576 and a spring 1578. The supporting shell and the spring are made from conducting materials. Spring 1578 is positioned between a first end of the conducting pin and an interior wall at a first end of supporting shell 1574, which provides a mechanical stop for spring 1578. The supporting shell has a second end opposite the first end. A portion opposite the first end of the conducting pin may move or slide through an opening 1579 at the second end of the supporting shell in response to the compressive force from the spring, thus providing spring-loading for conductive pin 1572.

FIG. 15C is a simplified side view of a module 1580 including PCB 20 represented in FIG. 3B including a multitude of the spring-loaded conductive pins 1572 represented in FIG. 15B installed in the multitude of notches 30, in accordance with one embodiment of the present invention. At least a portion of supporting shell 1574 may be adapted to install into notch 30 in PCB 20 as described above, but in lieu of directly and fixedly attaching a conductive pin at the notch. The second end of the conductive pin may electrically connect to the anisotropic conducting layer or the main-board via the compressively loaded spring and supporting shell to the electrical trace on the module, when the module is mounted on the main-board. Conducting pin 1576 may be spring-loaded to provide a predetermined loading force in the direction of longitudinal axis CLA and between the conducting pin and the anisotropic conducting layer, when module 1580 is mounted to the main-board with an anisotropic conducting layer between the conducting pin and the main board. The predetermined force may be sufficient to provide good electrical contact between the spring-loaded conducting pin and the anisotropic conducting layer, while not supplying an excessive force that may damage module 1580 when the module is mounted to the main-board. The spring-loaded conductive pin embodiment may be combined with any of the embodiments described above that facilitate the keying function or restraining notch or pin functions, for either buried, non-buried, or angled notches, for the blind notch either facing toward or facing away from the main-board, for the reinforcing film layer, or for the blunt tip embodiments, in any combination.

FIG. 16A is a simplified side view of a conductive pin 1600 including a flattened region 1610 at one end of conductive pin 1600, in accordance with one embodiment of the present invention. Conductive pin 1600 includes a pin width Pn along a portion 1620, in a direction substantially perpendicular to longitudinal axis CLA of the conducting pin. Conductive pin 1600 further includes a portion 1610 adjacent to a first end, which may be installed in one of the multitude of notches 30 described in reference to FIG. 3B. Referring again to FIG. 16A, flattened region 1610 is a broadened region extending from the first end to a predetermined location Lb along longitudinal axis CLA. Broadened region 1610 may be positioned or formed substantially centered on longitudinal axis CLA. Broadened region 1610 may be adapted to increase electrical contact between the conductive trace and the broadened region when the broadened region is installed in the notch. In another embodiment, broadened region 1610 may be adapted to reduce the pitch of the multitude of notches substantially in the direction of the intersection of the first plane and the second plane where the module interfaces to the main-board. In one embodiment, broadened region 1610 may increase a contact area between a portion of the notch and conductive pin 1600 to improve the strength of the module assembly.

Conductive pin 1600 further includes a second end located opposite the first end. Pin width Pn is a substantially constant value along longitudinal axis CLA from the second end to predetermined location Lb. Broadened region 1610 includes a width Pb that is wider than pin width Pn. FIG. 16B is a simplified top view of conductive pin 1600 represented in FIG. 16A, in accordance with one embodiment of the present invention, further showing flattened region 1610 at one end of conductive pin 1600.

FIG. 17 is a simplified side view of a module 1700 including PCB 20 represented in FIG. 3B including a multitude of the conductive pins 1600, each including the flattened region 1610 at one end of the conductive pin represented in FIG. 16A installed in the multitude of notches 30, in accordance with one embodiment of the present invention.

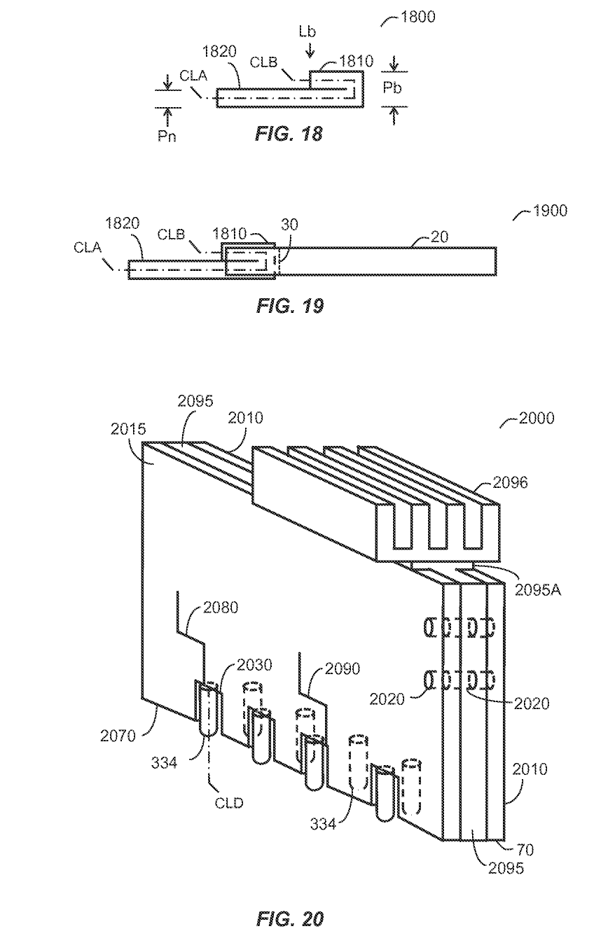

FIG. 18 is a simplified side view of a bent conductive pin 1800, in accordance with one embodiment of the present invention. Bent conductive pin 1800 includes a broadened region 1810 including a 180 degree bend at one end of the conductive pin such that conductive pin 1800 includes a longitudinal axis CLA and a longitudinal axis CLB substantially parallel to longitudinal axis CLA. Thus, the broadened region of conductive pin 1800 includes the surfaces of the conductive pin that are along both the longitudinal axis CLB and a portion 1810 of longitudinal axis CLA. Broadened region width Pb is thus about twice the width of the pin width Pn along a portion of the length of the pin at one end. FIG. 19 is a simplified side view of a module 1900 including PCB 20 represented in FIG. 3B including a multitude of bent conductive pins 1800 each represented in FIG. 18 installed in the multitude of notches 30, in accordance with one embodiment of the present invention. In one embodiment the broadened region may include a bend in the first conductive pin of any degree, for example 90 degree, 120 degree, and so on such that the bent region increases contact area between the portion of the notch sidewall and the conductive pin. The broadened region embodiments may be combined with any of the embodiments described above that facilitate the keying function or restraining notch or pin functions, for either vertical, horizontal, or angled mounting, for either buried with or without through-holes, non-buried, or angled notches, for the blind notch either facing toward or facing away from the main-board, for the reinforcing film layer, for the blunt tip, or for the spring-loaded conductive pin embodiments, in any combination.

FIG. 20 is a simplified perspective view of an assembly 2000 of a multitude of attached modules 2010 and 2015, coupled electrically or mechanically or coupled both electrically and mechanically, each similar to module 400 represented in FIG. 4C, in accordance with one embodiment of the present invention. At least one or both modules may include notches and conducting pins to accommodate a high number of connectors for connecting the mechanically coupled modules to the main-board. Module 2015 includes a component mounting surface substantially parallel to the first plane and an edge surface 2070 substantially parallel to the second plane. The component mounting surface of module 2015 includes a third area and edge surface 2070 includes a fourth area smaller than the third area. A multitude of conductive traces 2080 and 2090 of printed circuit 2015 is formed in a layer of printed circuit 2015 substantially parallel to the first plane. Printed circuit 2015 further includes a conductive pin 334, which in-turn includes a longitudinal axis CLD. A notch 2030 in printed circuit 2015 includes an opening through edge surface 2070 adapted to receive a portion of conductive pin 334 and adapted to electrically connect conductive pin 334 to one of the multitude of conductive traces 2080 of printed circuit 2015. Conductive pin 334 may be installed in notch 2030 such that longitudinal axis CLD is positioned substantially parallel to the first plane. In one embodiment, conductive pin 334 may be installed in notch 2030 such that longitudinal axis CLD is positioned substantially perpendicular to the second plane.

In one embodiment, a conductive via 2020 for connecting signals, power or ground may be embedded between adjacent attached modules. Conductive via 2020 may be adapted to electrically connect a corresponding one of the multitude of conductive traces of printed circuit 2015 to a corresponding one of the multitude of conductive traces of printed circuit 2010. In one embodiment, modules 2015 and 2010 may be attached at a few predetermined locations. In one embodiment, modules 2015 and 2010 may be attached substantially continuously using an in-fill or adhesive material across substantially all matching attachment surfaces. The attached modules embodiment may be combined with any of the embodiments described above that facilitate the keying function or restraining notch or pin functions, for either vertical, horizontal, or angled mounting, for either buried with or without through-holes, non-buried, or angled notches, for the blind notch either facing toward or facing away from the main-board, for the reinforcing film layer, for the blunt tip, for the spring-loaded conductive pin, or for the broadened region embodiments, in any combination.

In one embodiment, a thermally conducting and electrically insulating layer 2095 may be in contact with, sandwiched or disposed between modules 2015 and 2010. In one embodiment, the thermally conducting and electrically insulating layer 2095 may be formed such that a portion of thermally conducting and electrically insulating layer 2095A extends to a surface other than the surface adjacent the notches. Thermally conducting and electrically insulating layer 2095 may be provided to attach modules 2010 and 211. Thermally conducting and electrically insulating layer 2095 may be an epoxy adhesive with a thermally conducting but electrically insulating filler material such as boron nitride such as 3M™ Thermally Conductive Epoxy Adhesive TC-2810. A heat dissipater 2096 may be placed in contact with thermally conducting and electrically insulating layer 2095A. Heat dissipater 2096 may include a heat sink, a heat pipe, a heat sink with fan, or a thermoelectric cooler, and so on. It is understood that more than two modules may be attached together. In one embodiment, conducting via 2020 may be embedded in thermally conducting and electrically insulating layer 2095.

In one embodiment, a multitude of modules may be attached together forming a compact 3-D module with the plane of the component mounting surfaces on each module positioned substantially perpendicular to the component mounting surface of the main-board when the 3-D module is mounted to the main-board. The thermally conducting and electrically insulating layer and heat dissipater embodiment may be combined with any of the embodiments described above that facilitate the keying function or restraining notch or pin functions, for either vertical, horizontal, or angled mounting, for either buried with or without through-holes, non-buried, or angled notches, for the blind notch either facing toward or facing away from the main-board, for the reinforcing film layer, for the blunt tip, for the spring-loaded conductive pin, for the broadened region embodiment, or the attached modules embodiments in any combination.

In one embodiment, a multitude of conductors 2020 are embedded in thermally conducting and electrically insulating layer 2095. In one embodiment, a multitude of conductors 2020 are adapted to electrically connect a corresponding one of the multitude of conductive traces of printed circuit 2015 to a corresponding one of the multitude of conductive traces of printed circuit 2010. In one embodiment, only the first module includes notches and conductive pins such that the second module is mounted to the main-board via the first module. The second module is electrically connected to the main-board via the conductive pins of the first module. In one embodiment, a combination of conductors 2020 may connect the first module to the second module and both modules may include notches and corresponding conductive pins. In one embodiment, the component mounting surface is opposite the surfaces where modules 2015 and 2010 are attached. In one embodiment, semiconductor chips, other discrete components, or packaged discrete components may be mounted at the component mounting surfaces of modules 2015 and 2010. The conductors embedded in the thermally conducting and electrically insulating layer embodiment may be combined with any of the embodiments described above that facilitate the keying function or restraining notch or pin functions, for either vertical, horizontal, or angled mounting, for either buried with or without through-holes, non-buried, or angled notches, for the blind notch either facing toward or facing away from the main-board, for the reinforcing film layer, for the blunt tip, for the spring-loaded conductive pin, for the broadened region embodiment, or the attached modules embodiments in any combination.

The above embodiments of the present invention are illustrative and not limiting. Various alternatives and equivalents are possible. Although, the invention has been described with reference to a PCB by way of an example, it is understood that the invention is not limited by the terms board, base, or substrate so long as the base material may be manufactured with notch, blind notch or through-hole features without undue risk of breakage. The embodiments of the present invention are not limited by the type of material provided for the conductive pin. The embodiments of the present invention are not limited by the techniques for installing the conductive pin into the through-hole. The embodiments of the present invention are not limited by the size of the printed circuit, the size of the main-board, or the size relationship between the printed circuit and the main-board. The embodiments of the present invention are not limited by types of discrete components connected to the component mounting surface of the printed circuit, such as discrete passive components, microelectronic circuits, semiconductor circuits, other printed circuits or circuit boards, solar panels, thin-film-transistor arrays, and so on. The embodiments of the present invention are not limited by the techniques for attaching the conductive pin to the notch or conductive layer region overlaying the component mounting surface. Further, the invention may be used in electrically connecting one printed circuit to another printed circuit, not limited to permanent or removable electrical connections. Other additions, subtractions, or modifications are obvious in view of the present disclosure and are intended to fall within the scope of the appended claims.

What is claimed is:

1. An electric apparatus adapted to be connected to a first printed circuit, the electric apparatus comprising:
a second printed circuit including a first surface substantially parallel to a first plane and a second surface substantially parallel to a second plane perpendicular to the first plane, wherein the first surface includes a first area and the second surface includes a second area smaller than the first area;
a plurality of conductive traces formed in a layer of the second printed circuit substantially parallel to the first plane;
a first conductive pin including a first longitudinal axis;
a second conductive pin including a second longitudinal axis;
a first notch in the second printed circuit, the first notch including a first opening through the second surface adapted to receive a portion of the first conductive pin and adapted to electrically connect the first conductive pin to a first one of the plurality of conductive traces, wherein the first conductive pin is installed in the first notch such that the first longitudinal axis is positioned substantially parallel to the first plane; and
a second notch in the second printed circuit, the second notch including a second opening through the second surface adapted to receive a portion of the second conductive pin and adapted to electrically connect the second conductive pin to a second one of the plurality of conductive traces, wherein the second conductive pin is installed in the second notch such that the second longitudinal axis is positioned substantially parallel to the first plane.

2. The electric apparatus of claim 1 wherein the first conductive pin is installed in the first notch such that the first longitudinal axis is positioned substantially perpendicular to the second plane.

3. The electric apparatus of claim 1 wherein the first notch includes a first sidewall not parallel to the first plane, wherein a portion of the first sidewall is overlaid by a conductive layer.

4. The electric apparatus of claim 1 further comprising a conductive layer overlaying a portion of the first surface adjoining the first notch.

5. The electric apparatus of claim 1 wherein the first notch includes a first notch thickness in a direction substantially perpendicular to the first plane, wherein the second printed circuit includes a thickness equal to the first notch thickness.

6. The electric apparatus of claim 1 further comprising:
a third surface on the second printed circuit substantially parallel to a third plane perpendicular to the first plane and to the second plane; and
a third notch including an opening through the third surface, the third notch being adapted to engage with a clip or hook when the second printed circuit is connected to the first printed circuit.

7. The electric apparatus of claim 1 wherein the installation of the first conductive pin comprises at least one of soldered, press-fit, taped, glued, or glued with conductive paste into the first notch.

8. The electric apparatus of claim 1 further comprising an epoxy layer overlaying a portion of the first surface adjacent the first notch and overlaying a portion of the first conductive pin.

9. The electric apparatus of claim 1 further comprising a polyimide film including a sticky silicone adhesive overlaying a portion of the first surface adjacent the first notch and overlaying a portion of the first conductive pin.

10. The electric apparatus of claim 1 wherein the first conductive pin includes a first pin width in a direction substantially perpendicular to the first longitudinal axis, wherein the second conductive pin includes a second pin width in a direction substantially perpendicular to the second longitudinal axis, wherein the second pin width is substantially equal to the first pin width.

11. The electric apparatus of claim 1 wherein the first conductive pin includes a first pin width in a direction substantially perpendicular to the first longitudinal axis, wherein the second conductive pin includes a second pin width in a direction substantially perpendicular to the second longitudinal axis, wherein the second pin width is different than the first pin width.

12. The electric apparatus of claim 1 wherein the first conductive pin includes a first cross sectional area substantially perpendicular to the first longitudinal axis, wherein the second conductive pin includes a second cross sectional area substantially perpendicular to the second longitudinal axis, wherein the second cross sectional area is not equal to the first cross sectional area.

13. The electric apparatus of claim 1 wherein the first conductive pin comprises at least one of brass alloy, phosphor bronze alloy, tellurium copper alloy, or conductive carbon composite.

14. The electric apparatus of claim 1 wherein the first conductive pin is spring-loaded and partially enclosed by a supporting shell adapted to install into the first notch.

15. The electric apparatus of claim 1 wherein the first conductive pin includes a first pin width in a direction substantially perpendicular to the first longitudinal axis, wherein the first conductive pin includes:
a first end; and
a second end located opposite the first end, wherein the first pin width is a substantially constant value from the first end to the second end.

16. The electric apparatus of claim 1 wherein the first conductive pin includes a first length extending beyond the second surface and outside the first notch, wherein the second conductive pin includes a second length extending beyond the second surface and outside the second notch, wherein the second length is different than the first length.

17. The electric apparatus of claim 1 wherein the first conductive pin includes:
a first end, wherein a portion of the first conductive pin adjacent to the first end is installed in the first notch; and
a second end opposite the first end, wherein a portion adjacent to the second end of the first conductive pin includes threads adapted to receive a nut when the second printed circuit is connected to the first printed circuit.

18. The electric apparatus of claim 1 wherein the first conductive pin includes:
a first end, wherein a portion of the first conductive pin adjacent to the first end is installed in the first notch; and
a second end opposite the first end includes a substantially blunt tip.

19. The electric apparatus of claim 1 wherein the first conductive pin and the second conductive pin are not mechanically coupled until the first conductive pin and the second conductive pin are installed in the first notch and the second notch respectively.

20. The electric apparatus of claim 1 wherein the first notch includes a sidewall not parallel to the first plane, wherein a portion of the first conductive pin adjacent to a first end of the first conductive pin is installed in the first notch, the portion being in contact with the sidewall.

21. The electric apparatus of claim 1 further comprising:
a third conductive pin, wherein the third conductive pin includes a third longitudinal axis; and
a third notch in the second printed circuit, the third notch including a third opening through the second surface adapted to receive a portion of the third conductive pin and to electrically connect the third conductive pin to a third one of the plurality of conductive traces, wherein the third conductive pin is installed in the third notch such that the third longitudinal axis is positioned substantially parallel to the first plane, wherein the first notch is spaced apart from the second notch at a first spacing in a first direction substantially parallel to an intersection of the first plane and the second plane and the second notch is spaced apart from the third notch at a second spacing in the first direction, the second spacing being different than the first spacing.

22. The electric apparatus of claim 1 wherein the first notch includes a first notch thickness in a direction substantially perpendicular to the first plane, wherein the second printed circuit includes a thickness greater than the first notch thickness.

23. The electric apparatus of claim 22 wherein the first notch includes a third surface substantially parallel to the first plane.

24. The electric apparatus of claim 23 wherein a portion of the third surface is overlaid by a conductive layer.

25. The electric apparatus of claim 23 further comprising:
a through-hole located within a portion of the third surface and located away from the second surface, wherein the through-hole is adapted to receive the first conductive pin, wherein the first conductive pin further includes a third longitudinal axis substantially perpendicular to the first longitudinal axis, wherein a portion of the first conductive pin along the third longitudinal axis is installed in the through-hole, wherein a portion of the first conductive pin along the first longitudinal axis is installed in the first notch.

26. The electric apparatus of claim 25 wherein the through-hole includes a sidewall plated with a conductive material.

27. The electric apparatus of claim 1 wherein the first conductive pin includes at least one bend.

28. The electric apparatus of claim 27 wherein the first conductive pin further includes a third longitudinal axis at an angle not less than a right-angle from the first longitudinal axis, wherein a portion of the first conductive pin along the first longitudinal axis is installed in the first notch, wherein a portion of the first conductive pin along the third longitudinal axis is positioned substantially not parallel to the first plane.

29. The electric apparatus of claim 1 wherein the first conductive pin includes:
a first end, wherein a portion adjacent to the first end is installed in the first notch; and
a broadened region extending from the first end to a predetermined location along the first longitudinal axis, wherein the broadened region is adapted to increase contact between the first notch and the first conductive pin.

30. The electric apparatus of claim 29 wherein the broadened region includes a bend in the first conductive pin.

31. The electric apparatus of claim 29 wherein the broadened region includes a flattened region in the first conductive pin.

32. The electric apparatus of claim 1 further comprising:
a third printed circuit including a third surface substantially parallel to the first plane and a fourth surface substantially parallel to the second plane, wherein the third surface includes a third area and the fourth surface includes a fourth area smaller than the third area, wherein the third printed circuit is coupled to the second printed circuit;
a plurality of conductive traces of the third printed circuit formed substantially parallel to the first plane;
a third conductive pin including a third longitudinal axis; and
a third notch in the third printed circuit, the third notch including a third opening through the fourth surface adapted to receive a portion of the third conductive pin and adapted to electrically connect the third conductive pin to a first one of the plurality of conductive traces of the third printed circuit, wherein the third conductive pin is installed in the third notch such that the third longitudinal axis is positioned substantially parallel to the first plane.

33. The electric apparatus of claim 32 further comprising at least one conductor adapted to electrically connect a corresponding one of the plurality of conductive traces of the third printed circuit to a corresponding one of the plurality of conductive traces of the second printed circuit.

34. The electric apparatus of claim 32 further comprising a thermally conducting and electrically insulating layer disposed between the second printed circuit and the third printed circuit.

35. The electric apparatus of claim 34 further comprising a heat dissipater in contact with the thermally conducting and electrically insulating layer.

36. The electric apparatus of claim 34 wherein the thermally conducting and electrically insulating layer comprises a conduction via adapted to electrically connect a corresponding one of the plurality of conductive traces of the third printed circuit to a corresponding one of the plurality of conductive traces of the second printed circuit.

37. A method for electrically connecting a second printed circuit to a first printed circuit, the second printed circuit including a first surface substantially parallel to a first plane and a second surface substantially parallel to a second plane perpendicular to the first plane, wherein the first surface includes a first area and the second surface includes a second area smaller than the first area, wherein the second printed circuit further includes a plurality of conductive traces formed in a layer of the second printed circuit substantially parallel to the first plane, the method comprising:
providing a first conductive pin including a first longitudinal axis;
providing a second conductive pin including a second longitudinal axis;
receiving a portion of the first conductive pin through a first notch formed in the second surface of the second printed circuit;
receiving a portion of the second conductive pin through a second notch formed in the second surface of the second printed circuit;
installing the first conductive pin in the first notch such that the first longitudinal axis is positioned substantially parallel to the first plane;
installing the second conductive pin in the second notch such that the second longitudinal axis is positioned substantially parallel to the first plane;
electrically connecting the first conductive pin to a first one of the plurality of conductive traces of the second printed circuit; and
electrically connecting the second conductive pin to a second one of a plurality of conductive traces of the second printed circuit.

38. The method of claim 37 further comprising installing the first conductive pin in the first notch such that the first longitudinal axis is positioned substantially perpendicular to the second plane.

39. The method of claim 37 wherein the first notch includes a first sidewall not parallel to the first plane, wherein a portion of the first sidewall is overlaid by a conductive layer.

40. The method of claim 37 wherein a conductive layer overlays a portion of the first surface adjoining the first notch.

41. The method of claim 37 wherein the first notch includes a first notch thickness in a direction substantially perpendicular to the first plane, wherein the second printed circuit includes a thickness equal to the first notch thickness.

42. The method of claim 37 wherein the second printed circuit includes a third surface substantially parallel to a third plane perpendicular to the first plane and to the second plane, wherein the third surface includes a third notch through the third surface, the third notch engaging with a clip or hook when the second printed circuit is connected to the first printed circuit.

43. The method of claim 37 wherein installing the first conductive pin comprises at least one of soldering, press-fitting, taping, gluing, or gluing with conductive paste into the first notch.

44. The method of claim 37 further comprising overlaying an epoxy layer on a portion of the first surface adjacent the first notch and a portion of the first conductive pin.

45. The method of claim 37 further comprising overlaying a polyimide film including a sticky silicone adhesive on a portion of the first surface adjacent the first notch and a portion of the first conductive pin.

46. The method of claim 37 wherein the first conductive pin includes a first pin width in a direction substantially perpendicular to the first longitudinal axis, wherein the second conductive pin includes a second pin width in a direction substantially perpendicular to the second longitudinal axis, wherein the second pin width is substantially equal to the first pin width.

47. The method of claim 37 wherein the first conductive pin includes a first pin width in a direction substantially perpendicular to the first longitudinal axis, wherein the second conductive pin includes a second pin width in a direction substantially perpendicular to the second longitudinal axis, wherein the second pin width is different than the first pin width.

48. The method of claim 37 wherein the first conductive pin includes a first cross sectional area substantially perpendicular to the first longitudinal axis, wherein the second conductive pin includes a second cross sectional area substantially perpendicular to the second longitudinal axis, wherein the second cross sectional area is not equal to the first cross sectional area.

49. The method of claim 37 wherein the first conductive pin comprises at least one of brass alloy, phosphor bronze alloy, tellurium copper alloy, or conductive carbon composite.

50. The method of claim 37 wherein providing the first conductive pin includes spring-loading and partially enclosing the first conductive pin in a supporting shell adapted to install into the first notch.

51. The method of claim 37 wherein providing the first conductive pin includes:
forming a first pin width in a direction substantially perpendicular to the first longitudinal axis;
forming a first end; and
forming a second end located opposite the first end, wherein the first pin width is a substantially constant value from the first end to the second end.

52. The method of claim 37 wherein the first conductive pin includes a first length extending beyond the second surface and outside the first notch, wherein the second conductive pin includes a second length extending beyond the second surface and outside the second notch, wherein the second length is different than the first length.

53. The method of claim 37 wherein providing the first conductive pin includes:
forming a portion of the first conductive pin adjacent to a first end of the first conductive pin for installation into the first notch;
forming a second end of the first conductive pin opposite the first end; and
threading a portion of the first conductive pin adjacent to the second end for receiving a nut when the second printed circuit is connected to the first printed circuit.

54. The method of claim 37 wherein the first conductive pin includes:
a first end, wherein a portion of the first conductive pin adjacent to the first end is installed in the first notch; and
a second end opposite the first end including a substantially blunt tip.

55. The method of claim 37 wherein the first conductive pin and the second conductive pin are not mechanically coupled until the first conductive pin and the second conductive pin are installed in the first notch and the second notch respectively.

56. The method of claim 37 wherein the first notch includes a sidewall not parallel to the first plane, wherein a portion of the first conductive pin adjacent to a first end of the first conductive pin is installed in the first notch, the portion being in contact with the sidewall.

57. The method of claim 37 further comprising:
providing a third conductive pin, wherein the third conductive pin includes a third longitudinal axis;
receiving a portion of the third conductive pin through a third notch formed in the second surface of the second printed circuit, wherein the first notch is spaced apart from the second notch at a first spacing in a first direction substantially parallel to an intersection of the first plane and the second plane, wherein the second notch is spaced apart from the third notch at a second spacing in the first direction, the second spacing being different than the first spacing;
installing the third conductive pin in the third notch such that the third longitudinal axis is positioned substantially parallel to the first plane; and
electrically connecting the third conductive pin to a third one of the plurality of conductive traces of the second printed circuit.

58. The method of claim 37 further comprising:
providing an alignment fixture, wherein the alignment fixture includes a recess to align the first longitudinal axis substantially parallel to the first plane;
positioning the alignment fixture adjacent the first notch;
receiving the first conductive pin in the recess before installing the first longitudinal axis; and
aligning the first conductive pin along its first longitudinal axis substantially parallel to the first plane.

59. The method of claim 37 wherein the first notch includes a first notch thickness in a direction substantially perpendicular to the first plane, wherein the second printed circuit includes a thickness greater than the first notch thickness.

60. The method of claim 59 wherein the first notch includes a third surface substantially parallel to the first plane.

61. The method of claim 60 wherein a portion of the third surface is overlaid by a conductive layer.

62. The method of claim 60 further comprising:
providing the first conductive pin further including a third longitudinal axis substantially perpendicular to the first longitudinal axis;
installing a portion of the first conductive pin along its third longitudinal axis into a through-hole located within a portion of the third surface and away from the second surface; and
installing a portion of the first conductive pin along the first longitudinal axis in the first notch.

63. The method of claim 62 wherein the through-hole includes a sidewall plated with a conductive material.

64. The method of claim 37 wherein providing the first conductive pin includes forming the first conductive pin to include at least one bend.

65. The method of claim 64 wherein providing the first conductive pin further includes forming the first conductive pin to include a third longitudinal axis at an angle not less than a right-angle from the first longitudinal axis, wherein a portion of the first conductive pin along the first longitudinal axis is installed in the first notch, wherein a portion of the first conductive pin along the third longitudinal axis is positioned substantially not parallel to the first plane.

66. The method of claim 37 wherein providing the first conductive pin includes forming a broadened region extending from a first end of the first conductive pin to a predetermined location along the first longitudinal axis to increase contact between the first notch and the first conductive pin.

67. The method of claim 66 wherein providing the broadened region includes bending the first conductive pin.

68. The method of claim 66 wherein providing the broadened region includes flattening the first conductive pin.

69. The method of claim 37 further comprising:
coupling a third printed circuit to the second printed circuit, wherein the third printed circuit includes a third surface substantially parallel to the first plane and a fourth surface substantially parallel to the second plane, wherein the third surface includes a third area and the fourth surface includes a fourth area smaller than the third area, wherein the third printed circuit includes a plurality of conductive traces formed in a layer of the third printed circuit substantially parallel to the first plane;
providing a third conductive pin including a third longitudinal axis;
receiving a portion of the third conductive pin through a third notch formed in the fourth surface of the third printed circuit;
installing the third conductive pin in the third notch such that the third longitudinal axis is positioned substantially parallel to the first plane; and
electrically connecting the third conductive pin to a first one of the plurality of conductive traces of the third printed circuit.

70. The method of claim 69 wherein coupling includes connecting at least one conductor between a corresponding one of the plurality of conductive traces of the third printed circuit to a corresponding one of the plurality of conductive traces of the second printed circuit.

71. The method of claim 69 wherein coupling includes disposing a thermally conducting and electrically insulating layer between the second printed circuit and the third printed circuit.

72. The method of claim 71 wherein coupling includes connecting a heat dissipater to the thermally conducting and electrically insulating layer.

73. The method of claim 71 wherein the thermally conducting and electrically insulating layer comprises a conduction via electrically connecting a corresponding one of the plurality of conductive traces of the third printed circuit to a corresponding one of the plurality of conductive traces of the second printed circuit.

74. A method for electrically connecting a second printed circuit to a first printed circuit, the method comprising:
forming the second printed circuit including a first surface substantially parallel to a first plane and a second surface substantially parallel to a second plane perpendicular to the first plane, wherein the first surface includes a first area and the second surface includes a second area smaller than the first area
forming a plurality of conductive traces in a layer of the second printed circuit substantially parallel to the first plane;
forming a first notch in the second printed circuit, the first notch including a first opening through the second surface for receiving a portion of a first conductive pin substantially parallel to the first plane through the first opening and for electrically connecting the first conductive pin to a first one of the plurality of conductive traces when a portion of a first longitudinal axis of the first conductive pin is installed in the first notch; and
forming a second notch in the second printed circuit, the second notch including a second opening through the second surface for receiving a portion of a second conductive pin substantially parallel to the first plane through the second opening and for electrically connecting the second conductive pin to a second one of the plurality of conductive traces when a portion of a second longitudinal axis of the second conductive pin is installed in the second notch.

75. A first electric subassembly adapted to be connected to a second electric subassembly, the first electric subassembly comprising:
a plurality of planar bases wherein at least one of the plurality of planar bases includes;
a first surface substantially parallel to a first plane having a first area,
a second surface substantially parallel to a second plane perpendicular to the first plane having a second area smaller than the first area,
a plurality of electrically conductive traces arranged in the first plane,
a plurality of indentations in the second surface, and
a plurality of electrical conductors each being associated with and installed in a different one of the plurality of indentations, the plurality of electrical conductors each being associated with and electrically connected to a different one of the plurality of electrically conductive traces, wherein each of the plurality of electrical conductors includes an end extending beyond the second surface; and
at least one thermally conducting and electrically insulating layer disposed between at least a first subset of the plurality of planar bases.
